(19) United States
(12) Patent Application Publication
(10) Pub. No.: US 2026/0333983 A1
(43) Pub. Date: Oct. 22, 2026

(54) LIGHT-EMITTING SUBSTRATE AND MANUFACTURING METHOD THEREOF, AND DISPLAY APPARATUS

(71) Applicants: Beijing BOE Technology Development Co., Ltd., Beijing (CN); BOE Technology Group Co., Ltd., Beijing (CN)

(72) Inventors: Qian SUN, Beijing (CN); Mingxing WANG, Beijing (CN); Huajie YAN, Beijing (CN); Wei LI, Beijing (CN); Zhiqiang JIAO, Beijing (CN)

(73) Assignees: Beijing BOE Technology Development Co., Ltd., Beijing (CN); BOE Technology Group Co., Ltd., Beijing (CN)

(21) Appl. No.: 18/993,704

(22) PCT Filed: Oct. 31, 2023
(86) PCT No.: PCT/CN2023/128812

§ 371 Date: Jan. 13, 2025

(51) Int. Cl. H10H 29/851; H10H 29/01

(52) U.S. Cl. CPC H10H 29/8514; H10H 29/0361

(57) ABSTRACT

A light-emitting substrate includes a driving backplane, a device stack layer, an isolation structure, a second electrode and a color conversion layer. The device stack layer includes a bonding layer, a first electrode layer, a first semiconductor layer, a light-emitting layer and a second semiconductor layer. The bonding layer is bonded to the driving backplane. The isolation structure separates the device stack layer into a plurality of light-emitting devices. A first recess in a surface of the second semiconductor layer separates the second semiconductor layer into a plurality of coloring regions. The second electrode is disposed in the first recess. The color conversion layer is disposed in a plurality of second recesses in a coloring region. Orthographic projections of the coloring region and a light-emitting device corresponding to the coloring region on the driving backplane overlap, and the light-emitting device is connected to a driving circuit of the driving backplane.

### CROSS-REFERENCE TO RELATED APPLICATION

This application is a national phase entry under 35 USC 371 of International Patent Application No. PCT/CN2023/128812, filed on Oct. 31, 2023, which is incorporated herein by reference in its entirety.

### TECHNICAL FIELD

The present disclosure relates to the field of display technologies, and in particular, to a light-emitting substrate and a manufacturing method thereof, and a display apparatus.

### BACKGROUND

With the development of light-emitting diode technologies, micro light-emitting diodes (micro-LEDs) have been widely used. A micro-LED refers to an LED chip with a dimension less than 100 μm. The micro-LED has good performance in terms of brightness, service life, contrast, response time, power consumption, viewing angle and resolution, and has advantages such as self-luminous, simple structure, small size and energy-saving, and is regarded as a next generation display technology.

### SUMMARY

In an aspect, a light-emitting substrate is provided. The light-emitting substrate includes a driving backplane, a device stack layer, an isolation structure, a second electrode and a color conversion layer. The driving backplane includes a plurality of driving circuits. The device stack layer includes a bonding layer, a first electrode layer, a first semiconductor layer, a light-emitting layer, and a second semiconductor layer that are stacked in a direction away from the driving backplane. The bonding layer is bonded to the driving backplane. The isolation structure penetrates the bonding layer, the first electrode layer, the first semiconductor layer and the light-emitting layer, extends into the second semiconductor layer in a direction perpendicular to the driving backplane and away from the driving backplane, and separates the device stack layer into a plurality of light-emitting devices. A surface of the second semiconductor layer away from the driving backplane is provided with a first recess therein, the first recess separates the second semiconductor layer into a plurality of coloring regions, and the second electrode is at least partially disposed in the first recess. At least one coloring region is provided with a plurality of second recesses therein, and the color conversion layer is at least partially disposed in the plurality of second recesses. A light-emitting device of the plurality of light-emitting devices corresponds to a coloring region of the plurality of coloring regions, an orthographic projection of the coloring region on the driving backplane at least partially overlaps with an orthographic projection of the light-emitting device corresponding to the coloring region on the driving backplane, and the light-emitting device is connected to a driving circuit of the plurality of driving circuits.

In some embodiments, the plurality of second recesses are arranged in an array, and the plurality of second recesses have substantially a same structure.

In some embodiments, in the plurality of second recesses, at least two second recesses have different opening sizes, and/or at least two second recesses have different opening shapes, and/or at least two second recesses have different depths in a direction perpendicular to the second semiconductor layer.

In some embodiments, the plurality of coloring regions include a plurality of first coloring regions, a plurality of second coloring regions and a plurality of third coloring regions. The color conversion layer includes a plurality of first color conversion portions, a plurality of second color conversion portions and a plurality of third color conversion portions. A first color conversion portion is disposed in a first coloring region, and the first color conversion portion is configured to convert light emitted by a light-emitting device into a first color. A second color conversion portion is disposed in a second coloring region, and the second color conversion portion is configured to convert light emitted by another light-emitting device into a second color. A third color conversion portion is disposed in a third coloring region, and the third color conversion portion is configured to convert light emitted by yet another light-emitting device into a third color.

In some embodiments, the color conversion layer includes a plurality of fourth color conversion portions, a fourth color conversion portion is disposed in a plurality of second recesses of the coloring region, and the plurality of fourth color conversion portions are configured to convert light emitted by the plurality of light-emitting devices into a fourth color.

In some embodiments, a material of the second electrode includes a reflective material.

In some embodiments, in a direction perpendicular to the driving backplane and approaching the driving backplane, an end of the second electrode proximate to the driving backplane extends out of an end of the color conversion layer proximate to the driving backplane, and/or in the direction perpendicular to the driving backplane and away from the driving backplane, an end of the second electrode away from the driving backplane extends out of an end of the color conversion layer away from the driving backplane.

In some embodiments, the second electrode includes a stacked layer structure and a pad layer structure. The stacked layer structure includes a titanium layer, an aluminum layer, a nickel layer, and a gold layer that are stacked in the direction away from the driving backplane, or the stacked layer includes a chromium layer, a platinum layer, and a gold layer that are stacked in the direction away from the driving backplane. The pad layer structure is disposed on a side of the stacked layer structure away from the driving backplane, and a material of the pad layer structure includes at least one of tin, silver, and copper.

In some embodiments, the isolation structure includes a third recess, and an insulating layer and a reflective layer stacked on sidewalls and bottomwalls of the third recess. In the direction away from the driving backplane, the third recess penetrates the bonding layer, the first electrode layer, the first semiconductor layer and the light-emitting layer and extends into the second semiconductor layer. The insulating layer is located between the reflective layer and the third recess, and the reflective layer is configured to reflect light directed to the reflective layer.

In some embodiments, the third recess includes a plurality of first sub-recesses and a plurality of second sub-recesses. The plurality of first sub-recesses are arranged at intervals in a first direction and all extend in a second direction. The plurality of second sub-recesses are arranged at intervals in the second direction and all extend in the first direction. The plurality of first sub-recesses and the plurality of second sub-recesses intersect with each other to constitute a grid structure, and each square in the grid structure defines a light-emitting device. The first direction intersects with the second direction.

In some embodiments, in a direction perpendicular to a sidewall of the third recess, two portions of the reflective layer respectively covering two opposite sidewalls of the third recess have a first gap therebetween.

In some embodiments, in the direction perpendicular to the sidewall of the third recess, a dimension of the third recess is in a range of 2 μm to 3 μm, inclusive; and/or a thickness of the insulating layer is in a range of 0.5 μm to 1 μm, inclusive; and/or a thickness of the reflective layer is in a range of 50 nm to 150 nm, inclusive.

In some embodiments, an orthographic projection of the second electrode on the driving backplane is located in an orthographic projection of the isolation structure on the driving backplane.

In some embodiments, in a direction perpendicular to the driving backplane, the second electrode and the isolation structure have a second gap therebetween.

In some embodiments, the second electrode include a plurality of first sub-portions and a plurality of second sub-portions. The plurality of first sub-portions are arranged at intervals in a first direction and all extend in a second direction. The plurality of second sub-portions are arranged at intervals in the second direction and all extend in the first direction. The plurality of first sub-portions and the plurality of second sub-portions intersect with each other to constitute a grid structure, and each square in the grid structure defines a coloring region. The first direction intersects with the second direction.

In some embodiments, in a direction perpendicular to the driving backplane, a dimension of the color conversion layer is in a range of 3 μm to 5 μm, inclusive; and/or in a row direction in which the plurality of light-emitting devices are arranged, a dimension of the light-emitting device is in a range of 3 μm to 5 μm, inclusive; and in a column direction in which the plurality of light-emitting devices are arranged, a dimension of the light-emitting device is in a range of 3 μm to 5 μm, inclusive.

In another aspect, a display apparatus is provided. The display apparatus includes a driving circuit board and the light-emitting substrate according to any one of the above embodiments. The driving circuit board is connected to the light-emitting substrate and configured to transmit a control signal to the light-emitting substrate.

In yet another aspect, a manufacturing method of a light-emitting substrate is provided. The manufacturing method includes: forming a device stack layer on a base; forming an isolation structure in the device stack layer; providing a driving backplane and bonding the device stack layer to the driving backplane; removing the base; forming a plurality of second recesses in a surface of the second semiconductor layer away from the driving backplane; forming a first recess in the surface of the second semiconductor layer away from the driving backplane; forming a color conversion layer in the plurality of second recesses; and forming a second electrode in the first recess. The device stack layer includes a second semiconductor layer, a light-emitting layer, a first semiconductor layer, a first electrode layer, and a bonding layer that are sequentially arranged in a direction away from the base. The isolation structure penetrates the bonding layer, the first electrode layer, the first semiconductor layer and the light-emitting layer, extends into the second semiconductor layer, and separates the device stack layer into a plurality of light-emitting devices. The driving backplane includes a plurality of driving circuits, the bonding layer of the device stack layer is bonded to the driving backplane, and a light-emitting device of the plurality of light-emitting devices is connected to a driving circuit of the plurality of driving circuits. The second semiconductor layer is exposed, the second semiconductor layer includes a plurality of coloring regions arranged in an array, and any adjacent coloring regions have an isolation region therebetween. A part of the plurality of second recesses is located in the plurality of coloring regions, and another part of the plurality of second recesses is located in all isolation regions. The first recess is located in the all isolation regions.

In some embodiments, forming the isolation structure in the device stack layer includes: forming a third recess in the device stack layer; and sequentially forming an insulating layer and a reflective layer in the third recess. The third recess penetrates the bonding layer, the first electrode layer, the first semiconductor layer and the light-emitting layer, extends into the second semiconductor layer, and separates the device stack layer into the plurality of light-emitting devices. The insulating layer covers sidewalls and bottomwalls of the third recess, and the reflective layer covers a surface of the insulating layer away from the sidewalls and bottomwalls of the third recess and exposes a surface of the device stack layer away from the base.

In some embodiments, forming the plurality of second recesses in the surface of the second semiconductor layer away from the driving backplane includes: etching the second semiconductor layer by electrochemical etching to form the plurality of second recesses in the surface of the second semiconductor layer away from the driving backplane. In the plurality of second recesses, at least two second recesses have different opening sizes, and/or at least two second recesses have different opening shapes, and/or at least two second recesses have different depths in a direction perpendicular to the second semiconductor layer.

In some embodiments, forming the plurality of second recesses in the surface of the second semiconductor layer away from the driving backplane includes: forming an initial mask layer on the second semiconductor layer; forming an imprint pattern layer on the initial mask layer; etching the initial mask layer by using the imprint pattern layer as a mask to form a first mask layer; and etching the second semiconductor layer by using the first mask layer as a mask to form the plurality of second recesses in the second semiconductor layer. The initial mask layer covers the surface of the second semiconductor layer away from the driving backplane. The imprint pattern layer includes a plurality of imprint patterns, and an imprint pattern exposes a portion of the initial mask layer.

In some embodiments, the plurality of coloring regions are configured to convert light emitted by the plurality of light-emitting devices into light of a same color. After forming the plurality of second recesses in the surface of the second semiconductor layer away from the driving backplane, forming the color conversion layer in the plurality of second recesses firstly, and then forming the first recess in the surface of the second semiconductor layer away from the driving backplane.

In some embodiments, forming the color conversion layer in the plurality of second recesses includes: forming the color conversion layer in the plurality of second recesses by one of spin, drop coating and immersion. Forming the first recess in the surface of the second semiconductor layer away from the driving backplane includes: forming a second mask layer on the surface of the second semiconductor layer away from the driving backplane, the second mask layer covering the plurality of coloring regions and exposing the isolation regions; removing portions of the second semiconductor layer and the color conversion layer located in the isolation regions by using the second mask layer as a mask to form the first recess; and removing the second mask layer.

In some embodiments, the color conversion layer includes a plurality of first color conversion portions, a plurality of second color conversion portions and a plurality of third color conversion portions; the plurality of first color conversion portions are configured to convert light emitted by light-emitting devices into a first color, the plurality of second color conversion portions are configured to convert light emitted by another light-emitting devices into a second color, and the plurality of third color conversion portions are configured to convert light emitted by yet another light-emitting devices into a third color. After forming the plurality of second recesses in the surface of the second semiconductor layer away from the driving backplane, forming the first recess in the surface of the second semiconductor layer away from the driving backplane firstly, and then forming the color conversion layer in the plurality of second recesses.

In some embodiments, forming the first recess in the surface of the second semiconductor layer away from the driving backplane includes: forming a third mask layer on a side of the second semiconductor layer away from the driving backplane; removing a portion of the second semiconductor layer located in the isolation regions by using the third mask layer as a mask to form the first recess; and removing the third mask layer. The third mask layer is formed on the side of the second semiconductor layer away from the driving backplane, the third mask layer covers the plurality of coloring regions and exposes the isolation regions.

In some embodiments, the plurality of coloring regions include a plurality of first coloring regions, a plurality of second coloring regions and a plurality of third coloring regions; and forming the color conversion layer in the plurality of second recesses includes: forming a fourth mask layer on a side of the second semiconductor layer away from the driving backplane, the fourth mask layer covering the first recess, the plurality of second coloring regions and the plurality of third coloring regions and exposing the plurality of first coloring regions; forming a first color conversion layer on a surface of the fourth mask layer away from the driving backplane and in the plurality of first coloring regions; removing a portion of the first color conversion layer located on the surface of the fourth mask layer away from the driving backplane to form the plurality of first color conversion portions and removing the fourth mask layer; forming a fifth mask layer on the side of the second semiconductor layer away from the driving backplane, the fifth mask layer covering the first recess, the plurality of first coloring regions and the plurality of third coloring regions and exposing the plurality of second coloring regions; forming a second color conversion layer on a surface of the fifth mask layer away from the driving backplane and in the plurality of second coloring regions; removing a portion of the second color conversion layer located on the surface of the fifth mask layer away from the driving backplane to form the plurality of second color conversion portions and removing the fifth mask layer; forming a sixth mask layer on the side of the second semiconductor layer away from the driving backplane, the sixth mask layer covering the first recess, the plurality of first coloring regions and the plurality of second coloring regions and exposing the plurality of third coloring regions; forming a third color conversion layer on a surface of the sixth mask layer away from the driving backplane and in the plurality of third coloring regions; and removing a portion of the third color conversion layer located on a surface of the sixth mask layer away from the driving backplane to form the plurality of third color conversion portions and removing the sixth mask layer.

In some embodiments, before forming the color conversion layer in the plurality of second recesses, the manufacturing method further includes: surface-treating the plurality of second recesses to increase adhesion between a material of the color conversion layer and the plurality of second recesses.

### BRIEF DESCRIPTION OF THE DRAWINGS

In order to describe the technical solutions in the present disclosure more clearly, accompanying drawings to be used in some embodiments of the present disclosure will be briefly introduced below. Obviously, the accompanying drawings to be described below are merely accompanying drawings of some embodiments of the present disclosure, and a person of ordinary skill in the art can obtain other drawings according to those drawings. In addition, the accompanying drawings to be described below may be regarded as schematic diagrams, and are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a light-emitting substrate, in accordance with some embodiments;

FIG. 3 is a top view of a light-emitting substrate, in accordance with some embodiments;

FIG. 4A is a picture taken from a top view of second recesses by using a scanning electron microscope, in accordance with some embodiments;

FIG. 4B is a picture taken from a sectional view of second recesses by using a scanning electron microscope, in accordance with some embodiments;

FIG. 5 is a structural diagram of another light-emitting substrate, in accordance with some embodiments;

FIG. 6A is a picture taken from a top view of second recesses by using a scanning electron microscope, in accordance with some embodiments;

FIG. 6B is a picture taken from a sectional view of second recesses by using a scanning electron microscope, in accordance with some embodiments;

FIG. 7 is a structural diagram of yet another light-emitting substrate, in accordance with some embodiments;

FIG. 8 is a structural diagram of a second electrode, in accordance with some embodiments;

FIG. 9 is a structural diagram of still yet another light-emitting substrate, in accordance with some embodiments;

FIG. 10 is a structural diagram of still yet another light-emitting substrate, in accordance with some embodiments;

FIG. 11 is a structural diagram of an isolation structure, in accordance with some embodiments;

FIG. 12 is a structural diagram of still yet another light-emitting substrate, in accordance with some embodiments;

FIG. 13 is a flow diagram of a manufacturing process of a light-emitting substrate, in accordance with some embodiments; and

FIGS. 14 to 46 are each a diagram showing a step of a manufacturing process of a light-emitting substrate, in accordance with some embodiments.

### DETAILED DESCRIPTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should belong to the protection scope of the present disclosure.

Unless the context requires otherwise, the term “comprise” and other forms thereof such as the third-person singular form “comprises” and the present participle form “comprising” throughout the specification and the claims are construed as an open and inclusive meaning, i.e., “including, but not limited to”. In the description of the specification, the term such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or examples(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the feature. In the description of the embodiments of the present disclosure, the term “a/the plurality of” means two or more unless otherwise specified.

In the description of some embodiments, the terms “coupled” and “connected” and derivatives thereof may be used. The term “connected” should be understood in a broad sense; for example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact with each other. The term “coupled” or “communicatively coupled” may also mean that two or more components are not in direct contact with each other, but still cooperate or interact with each other. The embodiments disclosed herein are not necessarily limited to the contents herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The use of the phrase “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

As used herein, the term such as “about”, “substantially” or “approximately” includes a stated value and an average value within an acceptable range of deviation of a particular value, and the acceptable range of deviation is determined, for example, by a person of ordinary skill in the art, considering measurement in question and errors (i.e., limitations of a measurement system) associated with measurement of a particular quantity.

As used herein, the term such as “parallel”, “perpendicular” or “equal” includes a stated condition and a condition similar to the stated condition, and a range of the similar condition is within an acceptable range of deviation, and the acceptable range of deviation is determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shapes with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of regions in a device, and are not intended to limit the scope of the exemplary embodiments.

The related art provides a display apparatus, which includes a driving backplane, a plurality of LED chips disposed on the driving backplane, and a color conversion layer (a quantum dot film) disposed on a side of the LED chips away from the driving backplane. The plurality of LED chips may be transferred onto the driving backplane by the mass transfer technology, and the plurality of LED chips may emit light of the same color (e.g., blue). The color conversion layer may convert the light emitted by the plurality of LED chips into different colors, so that the display apparatus may achieve color display (displaying only part of the colors) or full-color display (displaying all the colors). However, in order to achieve an expected color conversion efficiency for the color conversion layer, the thickness of the color conversion layer is great and is generally around 10 μm, which is not conducive to the lightness and thinness of the display apparatus, and results in the high risk of cross-color between adjacent LED chips; moreover, the color conversion layer is generally formed by inkjet printing, and due to the resolution limitation of inkjet printer technology, the resolution of the color conversion layer is approximately 500 pixels per inch (PPI), which is not conducive to improving the resolution of the display apparatus.

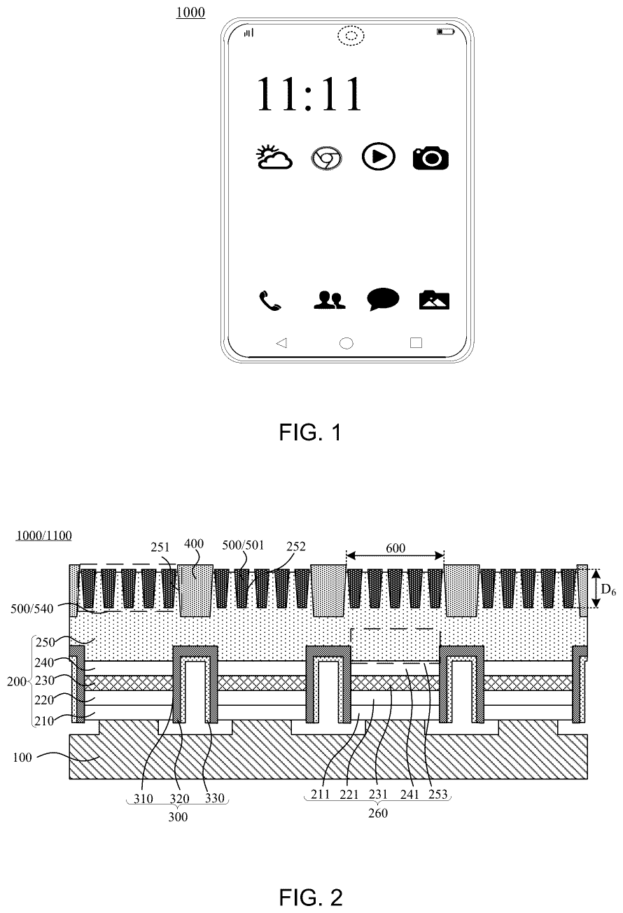

In order to solve the above technical problems, referring to FIG. 1, embodiments of the present disclosure provide a display apparatus 1000, and the display apparatus 1000 may be any apparatus that displays images whether in motion (e.g., a video) or stationary (e.g., static images), and whether textual or graphical.

For example, the display apparatus 1000 may be a mobile phone, a wireless device, a personal digital assistant (PDA), a wearable device, an augmented reality (AR) device, a virtual reality (VR) device, a hand-held or portable computer, a GPS receiver/navigator, a camera, a MP4 video player, a video camera, a game console, a watch, a clock, a calculator, a TV monitor, a flat panel display, a computer monitor, a car display (e.g., an odometer display), a cockpit controller and/or display, a camera view display (e.g., a rear view camera display in a vehicle), an electronic photo, an electronic billboard or indicator, a projector, a packaging, an aesthetic structure (e.g., a display for displaying an image of a piece of jewelry), or the like. For example, as shown in FIG. 1, the display apparatus 1000 may be a mobile phone.

Referring to FIG. 2, the display apparatus 1000 includes a light-emitting substrate 1100 and a driving circuit board (not shown in the figure). The driving circuit board is connected to the light-emitting substrate 1100 and is configured to transmit a control signal to the light-emitting substrate 1100 to drive the light-emitting substrate 1100 to emit light. In addition, the display apparatus 1000 may further include a touch structure, an under-screen camera and an under-screen fingerprint recognition sensor, such that the display apparatus 1000 can realize various functions such as touch, photography, video recording, fingerprint recognition or face recognition, which are not specifically limited here.

With continued reference to FIG. 2, the light-emitting substrate 1100 includes a driving backplane 100, a device stack layer 200, an isolation structure 300, a second electrode 400 and a color conversion layer 500.

In some embodiments, the driving backplane 100 may be, for example, a backplane in a backlight module of a liquid crystal display (LCD) apparatus. In this case, the light-emitting substrate 1100 may be used as the backlight source in the LCD, and the display apparatus further includes a liquid crystal display panel, and the liquid crystal display panel is disposed on a light exit side of the light-emitting substrate. The light-emitting substrate 1100 is used to provide backlight for the liquid crystal display panel, and the liquid crystal display panel can adjust the intensity (grayscale) of light passing through the liquid crystal display panel, thereby achieving image display.

In some other embodiments, the driving backplane 100 may be, for example, a display backplane. In this case, the light-emitting substrate 1100 may be directly used as an LED display apparatus. The LED display apparatus may be, for example, a micro LED display apparatus.

With continued reference to FIG. 2, the device stack layer 200 includes a bonding layer 210, a first electrode layer 220, a first semiconductor layer 230, a light-emitting layer 240 and a second semiconductor layer 250 that are stacked in a direction away from the driving backplane 100. The bonding layer 210 is bonded to the driving backplane 100.

In some embodiments, the bonding layer 210 is configured to be bonded to the driving backplane 100, and a material of the bonding layer 210 may include a molybdenum-titanium-nickel alloy (MTD) or gold (Au). A material of the first electrode layer 220 may include a transparent conductive material or a metal material; the transparent conductive material may include indium tin oxide (ITO); the metal material may include at least one of gold, silver, copper, titanium and aluminum.

In an example, the material of the bonding layer 210 may be gold, and a thickness of the bonding layer 210 may in a range of 1 μm to 2 μm; for example, the thickness of the bonding layer 210 may be 1 μm, 1.3 μm, 1.5 μm, 1.7 μm or 2 μm. The bonding layer 210 may reflect the light emitted by the light-emitting layer 240, such that the light is emitted as much as possible from a side of the device stack layer 200 away from the driving backplane 100. The material of the first electrode layer 220 may be ITO, and a thickness of the first electrode layer 220 may be in a range of 100 nm to 140 nm; for example, the thickness of the first electrode layer 220 may be 100 nm, 120 nm, 135 nm, or 140 nm.

A material of the first semiconductor layer 230 may be a P-type semiconductor material, and correspondingly, a material of the second semiconductor layer 250 may be an N-type semiconductor material. Alternatively, the material of the first semiconductor layer 230 may be an N-type semiconductor material, and correspondingly, the material of the second semiconductor layer 250 may be a P-type semiconductor material. There are various materials of the first semiconductor layer 230 and the second semiconductor layer 250, which may be flexibly selected according to actual needs. For example, an intrinsic semiconductor material of the first semiconductor layer 230 and an intrinsic semiconductor material of the second semiconductor layer 250 are the same, and the intrinsic semiconductor material may be any one of gallium nitride (GaN), gallium phosphide (GaP), aluminum gallium arsenide (AlGaAs) and aluminum gallium indium phosphide (AlGaInP). A P-type doping process is performed on the intrinsic semiconductor material of one of the first semiconductor layer 230 and the second semiconductor layer 250 to form the P-type semiconductor material, and an N-type doping process is performed on the intrinsic semiconductor material of the other to form the N-type semiconductor material. A PN junction may be formed between the first semiconductor layer 230 and the second semiconductor layer 250. The light-emitting layer 240 may be a multiple quantum well (MQW) layer; for example, a material of the light-emitting layer 240 may be gallium nitride (GaN). The first semiconductor layer 230, the light-emitting layer 240, and the second semiconductor layer 250 may also be referred to as epitaxial structures.

In an example, the material of the first semiconductor layer 230 is P-type doped gallium nitride (P-GaN), and a thickness of the first semiconductor layer 230 may be in a range of 0.1 μm to 0.2 μm. For example, the thickness of the first semiconductor layer 230 may be 0.1 μm, 0.15 μm, 0.18 μm, or 0.2 μm. The material of the light-emitting layer 240 is gallium nitride, and the thickness of the light-emitting layer 240 may be in a range of 0.1 μm to 0.15 μm. For example, the thickness of the light-emitting layer 240 may be 0.1 μm, 0.12 μm, 0.14 μm or 0.15 μm. The material of the second semiconductor layer 250 is N-type doped gallium nitride (N-GaN), and a thickness of the second semiconductor layer 250 is in a range of 3 μm to 5 μm. For example, the thickness of the second semiconductor layer 250 is 3 μm, 3.5 μm, 4 μm, 4.8 μm or 5 μm.

With continued reference to FIG. 2, in a direction (a direction from bottom to top in FIG. 2) perpendicular to the driving backplane 100 and away from the driving backplane 100, the isolation structure 300 penetrates the bonding layer 210, the first electrode layer 220, the first semiconductor layer 230 and the light-emitting layer 240, and the isolation structure 300 extends into the second semiconductor layer 250. The isolation structure 300 separates the device stack layer 200 into a plurality of light-emitting devices 260. Each light-emitting device 260 may include a bonding pattern 211 located in the bonding layer 210, a first electrode pattern 221 located in the first electrode layer 220, a first semiconductor pattern 231 located in the first semiconductor layer 230, a light-emitting pattern 241 located in the light-emitting layer 240, and a second semiconductor pattern 253 located in the second semiconductor layer 250. The bonding pattern 211 of a light-emitting device 260 is bonded (connected) to a driving circuit of the driving backplane 100, so that a driving circuit drives a light-emitting device 260 to emit light.

It will be understood that, the isolation structure 300 separates the bonding layer 210 into a plurality of bonding patterns 211 that are separated from each other, which means that the bonding layer 210 includes the plurality of (all) bonding patterns 211 included in the plurality of (all) light-emitting devices 260. Similarly, the first electrode layer 220 includes a plurality of first electrode patterns 221 that are separated from each other, the first semiconductor layer 230 includes a plurality of first semiconductor patterns 231 that are separated from each other, and the light-emitting layer 240 includes a plurality of light-emitting patterns 241. The second semiconductor pattern 253 refers to a portion of the second semiconductor layer 250 that coincides with a projection of the light-emitting pattern 241; that is, in a same light-emitting device 260, an orthographic projection of the second semiconductor pattern 253 on the driving backplane 100 coincides with an orthographic projection of the light-emitting pattern 241 on the driving backplane 100.

The isolation structure 300 does not penetrate the second semiconductor layer 250, and the second semiconductor patterns 253 of the plurality of light-emitting devices 260 are connected to each other into a whole; that is, the isolation structure 300 does not separate the device stack layer 200 into light-emitting devices 260 independent from each other. In this way, the plurality of light-emitting devices 260 do not need to be transferred to the driving backplane 100 by the mass transfer technology. For example, the device stack layer 200 may be bonded into a whole by high-precision alignment bonding, which helps to reduce the difficulty of manufacturing the light-emitting substrate 1100.

It will be understood that, in a case where different voltages are respectively applied to a first semiconductor pattern 231 and a second semiconductor pattern 253 of a light-emitting device 260 to create an electric field between the first semiconductor pattern 231 and the second semiconductor pattern 253, minority carriers and majority carriers may recombine in the light-emitting pattern 241, and the excess energy is released in a form of light, whereby electric energy is converted into light energy. The plurality of second semiconductor patterns 253 of the plurality of light-emitting devices 260 are connected to each other into a whole, so that voltages applied to the plurality of second semiconductor patterns 253 are equal. A driving circuit in the driving backplane 100 is electrically connected to the first semiconductor pattern 231 sequentially through the bonding pattern 211 and the first electrode pattern 221, so that the driving backplane 100 may apply a same or different voltages to the first semiconductor patterns 231 of different light-emitting devices 260 to drive the different light-emitting devices 260 to emit light of the same or different intensities. The light-emitting patterns 241 of the plurality of light-emitting devices 260 are made of a same material, so that the plurality of light-emitting devices 260 can emit light of a same color; for example, the plurality of light-emitting devices 260 all emit blue light.

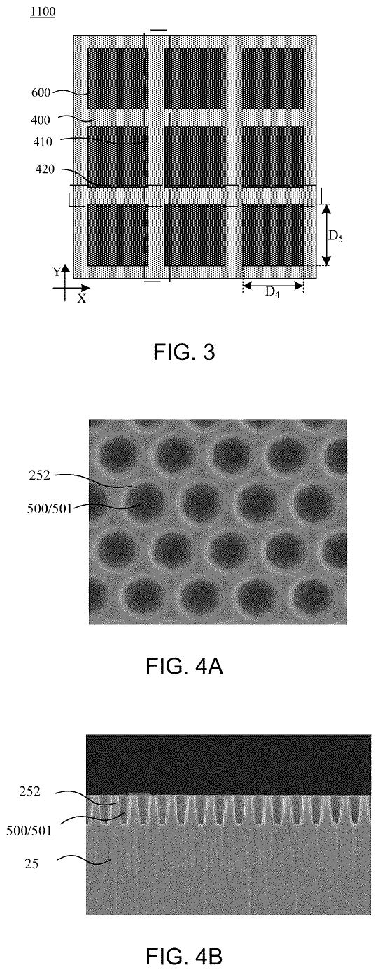

Referring to FIGS. 2 and 3, a first recess 251 is provided in a surface (the upper surface of the second semiconductor layer 250 in FIG. 2) of the second semiconductor layer 250 away from the driving backplane 100, and the first recess 251 separates the second semiconductor layer 250 into a plurality of coloring regions 600. At least a portion of the second electrode 400 is disposed in the first recess 251, and the second electrode 400 is connected to the second semiconductor layer 250, so that a voltage may be applied to the second semiconductor layer 250 through the second electrode 400. It will be understood that, since the second electrode 400 is disposed in the first recess 251, as shown in FIG. 2, a part of borders (a border of a portion located in the first recess 251) of the second electrode 400 coincides with a border of the first recess 251.

Referring to FIG. 2, a light-emitting device 260 corresponds to a coloring region 600, and an orthographic projection of the coloring region 600 on the driving backplane 100 at least partially overlaps with an orthographic projection of the light-emitting device 260 corresponding to the coloring region 600 on the driving backplane 100, such that the light emitted by the light-emitting device 260 can be directed to the coloring region 600 corresponding to the light-emitting device 260 and emitted after being color-converted by a color conversion layer in the coloring region 600.

At least one coloring region 600 is provided with a plurality of second recesses 252 therein, and the plurality of second recesses 252 are disposed in the surface of the second semiconductor layer 250 away from the driving backplane 100. For example, each of the plurality of coloring regions 600 is provided with a plurality of second recesses 252 therein; that is, each coloring region 600 is provided with a plurality of second recesses 252 therein.

In some embodiments, referring to FIGS. 2, 4A and 4B, the plurality of second recesses 252 are arranged in an array, and the structures of the plurality of second recesses 252 are substantially the same. In other words, the plurality of second recesses 252 are evenly distributed, and different second recesses 252 have substantially the same opening size, opening shape, and depth in a direction perpendicular to the second semiconductor 250. In this way, a plurality of color conversion blocks 501 in the color conversion layer 500 are evenly distributed, the sizes of different color conversion blocks are the same, and the structures of different color conversion blocks are the same, which may improve the uniformity of color conversion in different coloring regions. It will be noted that, in FIGS. 4A and 4B, an opening shape of a second recess 252 is circular, and in some other embodiments, the opening shape of the second recess 252 may be rectangular, elliptical or other shapes, which is not specifically limited in the embodiments of the present disclosure.

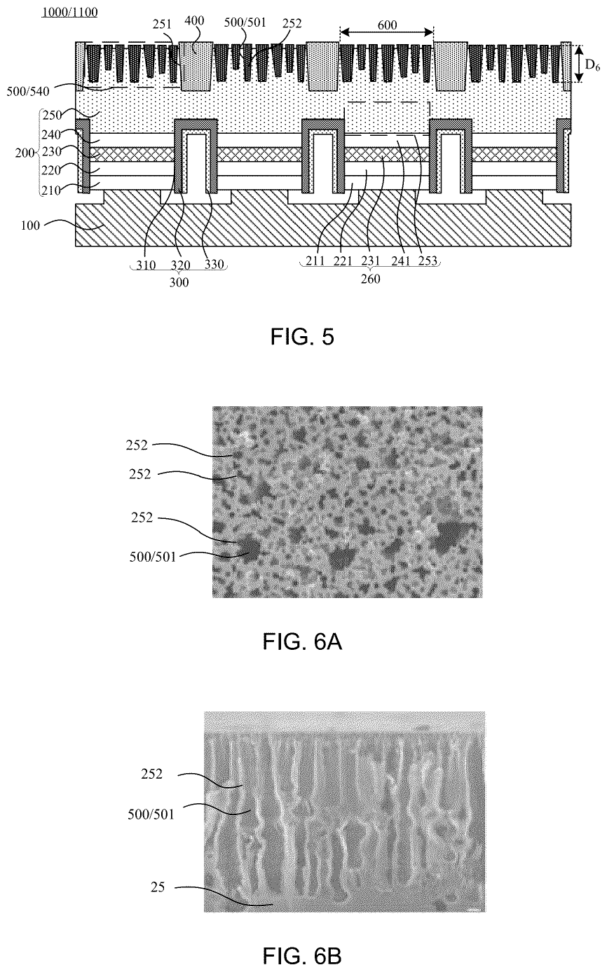

In some other embodiments, referring to FIGS. 5, 6A and 6B, among the plurality of second recesses 252, at least two second recesses 252 have different opening sizes, and/or at least two second recesses 252 have different opening shapes, and/or at least two second recesses 252 have different depths in the direction perpendicular to the second semiconductor layer 250. That is, among the plurality of second recesses 252, structures of part of the second recesses are not completely identical, which means that the structures and distribution positions of the plurality of second recesses 252 are irregular. In this way, the plurality of second recesses 252 may be formed by electrochemical etching, which is conducive to simplifying the manufacturing process of the second recesses 252 to reduce the difficulty of forming the second recesses 252 and reduce the manufacturing cost of the light-emitting substrate 1100.

For example, as shown in FIGS. 6A and 6B, at least two second recesses 252 have different opening sizes, at least two second recesses have different opening shapes, and at least two second recesses 252 have different depths in the direction perpendicular to the second semiconductor layer 250.

As shown in FIG. 5, the color conversion layer 500 is disposed in the second recesses 252, and light will be refracted and reflected at an interface between the second semiconductor layer 250 and the color conversion layer 500. The color conversion layer 500 located in a second recess 252 is referred to as a color conversion block 501. When the light-emitting substrate 1100 is in operation, light emitted by a light-emitting device 260 is directed to a coloring region 600 corresponding to the light-emitting device 260, and in the process of passing through the color conversion layer 500 in the coloring region 600, the light will be reflected and refracted multiple times in the color conversion blocks 501 and the second semiconductor layer 250, thereby increasing the optical path of the light propagating in the color conversion layer 500, so as to increase the efficiency of the color conversion layer 500 in absorbing light and increase the color conversion efficiency of the color conversion layer 500 for the light. In this way, the thickness of the color conversion layer 500 may be reduced without reducing the color conversion efficiency of the color conversion layer 500 for the light, which helps to reduce the thickness of the light-emitting substrate 1100 and facilitates the lightness and thinness of the display apparatus 1000.

In some embodiments, as shown in FIGS. 2 and 5, in the direction perpendicular to the driving backplane 100, a dimension of the color conversion layer 500 is D₆, and the value of D₆ is in a range of 3 μm to 5 μm; that is, the thickness of the color conversion layer 500 is in the range of 3 μm to 5 μm. In comparison with the quantum dot film (about 10 μm) in the related art, the thickness of the color conversion layer 500 can be greatly reduced, which facilitates the lightness and thinness of the light-emitting substrate 1100. For example, the value of D₆ may be 3 μm, 3.5 μm, 4 μm, 4.6 μm or 5 μm, which will not be individually enumerated in the embodiments of the present disclosure.

It will be noted that, as shown in FIG. 5, in the case where depths of at least two second recesses 252 among the plurality of second recesses 252 are different, the thickness of the color conversion layer 500 may be an average thickness of the color conversion layer 500, i.e., an average thickness of the plurality of color conversion blocks 501.

The material of the color conversion layer 500 includes a wavelength conversion material, and the wavelength conversion material may include cadmium-based quantum dots, indium-based quantum dots, perovskite-based quantum dots, rare earth phosphors, an organic fluorescent material, etc.; the wavelength conversion properties of these materials may be used to convert the light emitted by the light-emitting devices 260 into other colors, thereby achieving multi-color or even full-color display. As an example, the material of the color conversion layer 500 is a quantum dot (QD) material. For example, in the case where the light-emitting device 260 emits blue light, the color conversion layer 500 may convert the blue light into red or green.

It will be understood that, the materials of the color conversion layer 500 in the plurality of coloring regions 600 may be completely the same, so as to convert the light emitted by the plurality of light-emitting devices 260 into light of a same color to be emitted. Alternatively, the materials of the color conversion layer 500 in at least part of the coloring regions 600 may be different, so as to convert the light emitted by the plurality of light-emitting devices 260 into light of different colors to be emitted.

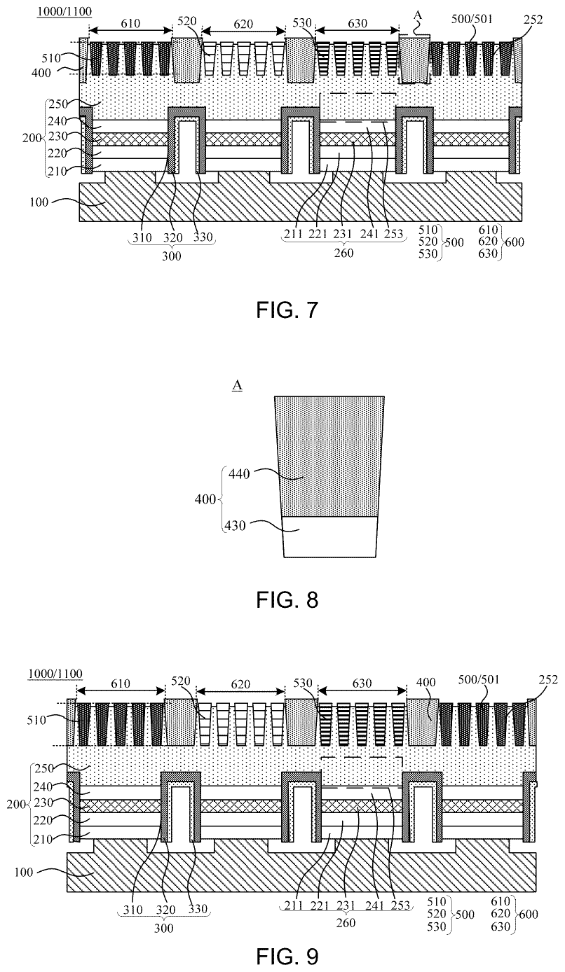

In some embodiments, referring to FIG. 7, the plurality of coloring regions 600 includes a plurality of first coloring regions 610, a plurality of second coloring regions 620 and a plurality of third coloring regions 630. The color conversion layer 500 includes a plurality of first color conversion portions 510, a plurality of second color conversion portions 520, and a plurality of third color conversion portions 530. In FIG. 7, different filling patterns represent different color conversion portions. FIG. 7 only exemplarily shows two first coloring regions 610, one second coloring region 620 and one third coloring region 630, and correspondingly, FIG. 7 exemplarily shows two first color conversion portions 510, one second color conversion portion 520 and one third color conversion portion 530. The arrangement positions and areas of the first coloring regions 610, the second coloring regions 620, and the third coloring regions 630 may be flexibly set as needed, which is not specifically limited in the embodiments of the present disclosure.

A first color conversion portion 510 is disposed in a first coloring region 610, and the first color conversion portion 510 is configured to convert light emitted by a light-emitting device 260 into a first color. A second color conversion portion 520 is disposed in a second coloring region 620, and the second color conversion portion 520 is configured to convert light emitted by a light-emitting device 260 into a second color. A third color conversion portion 530 is disposed in a third coloring region 630, and the third color conversion portion 530 is configured to convert light emitted by a light-emitting device into a third color. For example, the first color, the second color, and the third color may be red, green, and blue, respectively, so that the light-emitting substrate 1100 can achieve full-color display.

Of course, in some other embodiments, the first color, the second color and the third color may be other color combinations, which is not specifically limited in the embodiments of the present disclosure. Alternatively, in some other embodiments, the color conversion layer 500 may include two or four types of color conversion portions to convert the light emitted by the plurality of light-emitting devices 260 into two colors or four colors, which is not specifically limited in the present disclosure as long as the same technical concept is adopted.

In some other embodiments, referring to FIGS. 2 and 5, the color conversion layer 500 includes a plurality of fourth color conversion portions 540, and a fourth color conversion portion 540 is disposed in a coloring region 600; that is, the color conversion layer 500 is used to convert all the light emitted by multiple (all) light-emitting devices 260 into a fourth color, and the light-emitting substrate 1100 is configured to emit light of a single color. The fourth color may be red, green, blue or any other desired color, and is not specifically limited here, as long as the same technical concept is adopted.

In some embodiments, a material of the second electrode 400 includes a reflective material. Thus, light emitted from a coloring region 600 and directed to the second electrode is reflected at the surface of the second electrode 400 and still propagates in the coloring region 600, and will not propagate to an adjacent coloring region 600, which may reduce the risk of cross-color between adjacent coloring regions 600.

For example, the material of the second electrode 400 may include one or more of titanium (Ti), aluminum (Al), nickel (Ni), gold (Au), chromium (Cr), platinum (Pt), copper (Cu), silver (Ag), and tin (Sn).

In some embodiments, referring to FIGS. 7 and 8, the second electrode 400 may include a stacked layer structure 430 and a pad layer structure 440 disposed on a side of the stacked layer structure 430 away from the driving backplane 100. The stacked layer structure 430 may include a titanium layer, an aluminum layer, a nickel layer, and a gold layer that are stacked in a direction away from the driving backplane 100, or the stacked layer structure 430 may include a chromium layer, a platinum layer, and a gold layer that are stacked in the direction away from the driving backplane 100. The first stack is used to form an ohmic contact with the second semiconductor layer 250, which helps to reduce the impedance of the second electrode 400. A material of the pad layer structure 440 may include at least one of tin, silver, and copper. In a case where the pad layer structure 440 includes multiple layers of metal, the arrangement order of the multiple layers of metal in the second stack may be arbitrarily adjusted. The second stack is used to increase the thickness of the second electrode 400 to meet certain requirements.

In the case where the stacked layer structure 430 includes a titanium layer, an aluminum layer, a nickel layer and a gold layer, a thickness of the titanium layer may be in a range of 15 nm to 30 nm; for example, the thickness of the titanium layer may be 15 nm, 20 nm, 23 nm or 30 nm; a thickness of the aluminum layer may be in a range of 50 nm to 200 nm; for example, the thickness of the aluminum layer may be 50 nm, 80 nm, 145 nm or 200 nm; a thickness of the nickel layer may be in a range of 20 nm to 50 nm; for example, the thickness of the nickel layer may be 20 nm, 35 nm, 40 nm or 50 nm; a thickness of the aluminum layer may be in a range of 50 nm to 350 nm; for example, the thickness of the aluminum layer may be 50 nm, 85 nm, 100 nm, 200 nm, 300 nm or 350 nm. In the case where the stacked layer structure 430 includes a chromium layer, a platinum layer and a gold layer, a thickness of the chromium layer may be in a range of 40 nm to 60 nm; for example, the thickness of the chromium layer may be 40 nm, 50 nm, 55 nm or 60 nm; a thickness of the platinum layer may be in a range of 15 nm to 25 nm; for example, the thickness of the platinum layer may be 15 nm, 20 nm, 23 nm or 25 nm; a thickness of the gold layer may be in a range of 150 nm to 350 nm; for example, the thickness of the gold layer may be 150 nm, 200 nm, 250 nm, 320 nm or 350 nm.

In some embodiments, referring to FIG. 7, in a direction (a direction from top to bottom in FIG. 7) perpendicular to the driving backplane 100 and approaching the driving backplane 100, an end (the lower surface) of the second electrode 400 proximate to the driving backplane 100 extends out of an end of the color conversion layer 500 proximate to the driving backplane 100; that is, the depth of the second recess 252 is less than the depth of the first recess 251, such that the lower surface of the second electrode 400 is closer to the driving backplane than the lower surface of the color conversion layer 500. In this way, the risk that the light being color-converted by the color conversion layer 500 in a coloring region 600 is directed from a side of the second electrode 400 proximate to the driving backplane 100 to an adjacent coloring region 600 may be reduced.

In the direction (the direction from bottom to top in FIG. 7) perpendicular to the driving backplane 100 and away from the driving backplane 100, an end of the second electrode 400 away from the driving backplane 100 extends out of an end of the color conversion layer 500 away from the driving backplane 100; that is, the upper surface of the second electrode 400 is further away from the driving backplane 100 than the upper surface of the color conversion layer 500. In this way, at least part of the light emitted from the color conversion layer 500 and diverging in every direction may be directed to a surface of a portion of the second electrode 400 extending out of the color conversion layer 500 and may be reflected, which can increase the light emitted from directly above the coloring regions 600 and reduce the risk of cross-color in the light from adjacent coloring regions 600.

For example, as shown in FIG. 7, in the direction perpendicular to the driving backplane 100 and approaching the driving backplane 100, the end of the second electrode 400 proximate to the driving backplane 100 extends out of the end of the color conversion layer 500 proximate to the driving backplane 100; and in the direction perpendicular to the driving backplane 100 and away from the driving backplane 100, the end of the second electrode 400 away from the driving backplane 100 extends out of the end of the color conversion layer 500 away from the driving backplane 100.

In some other examples, referring to FIG. 9, in the direction perpendicular to the driving backplane 100, the end of the second electrode 400 proximate to the driving backplane 100 is substantially flush with the end of the color conversion layer 500 proximate to the driving backplane 100; and in the direction perpendicular to the driving backplane 100 and away from the driving backplane 100, the end of the second electrode 400 away from the driving backplane 100 extends out of the end of the color conversion layer 500 away from the driving backplane 100.

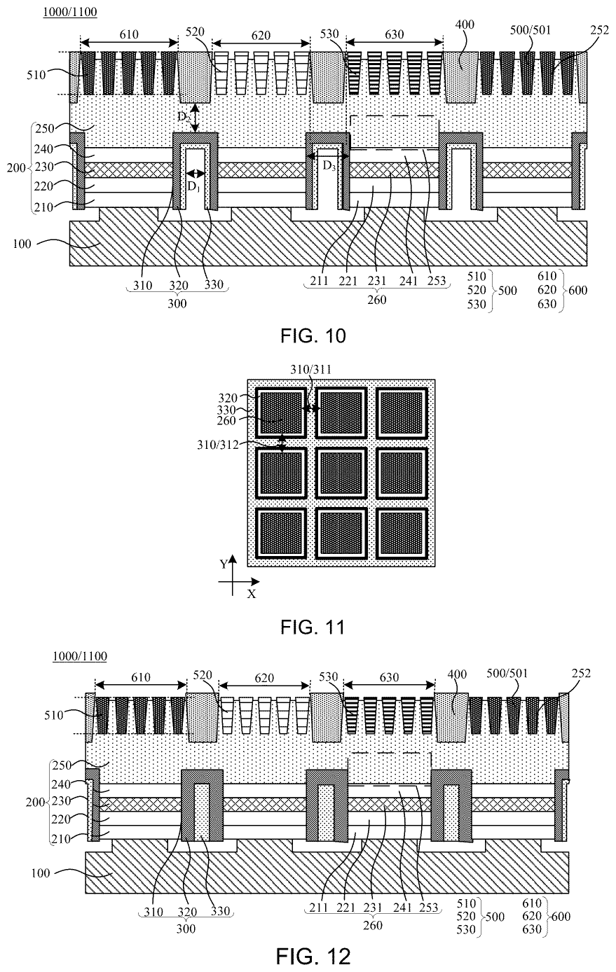

In some other examples, referring to FIG. 10, in the direction perpendicular to the driving backplane 100 and approaching the driving backplane 100, the end of the second electrode 400 proximate to the driving backplane 100 extends out of the end of the color conversion layer 500 proximate to the driving backplane 100; and in the direction perpendicular to the driving backplane 100, the end of the second electrode 400 away from the driving backplane 100 is substantially flush with the end of the color conversion layer 500 away from the driving backplane 100.

In some embodiments, referring to FIGS. 7 and 10, the isolation structure 300 includes a third recess 310 and an insulating layer 320 and a reflective layer 330 sequentially disposed in the third recess 310. In the direction (the direction from bottom to top in FIG. 10) away from the driving backplane 100, the third recess 310 penetrate the bonding layer 210, the first electrode layer 220, the first semiconductor layer 230 and the light-emitting layer 240, and extend into the second semiconductor layer 250. The third recess 310 are configured to separate the device stack layer 200 into the plurality of light-emitting devices 260. The insulating layer 320 is configured to protect a sidewall of the light-emitting device 260 exposed by the third recess 310, and to separate the reflective layer 330 from the light-emitting device 260, especially to separate the reflective layer 330 from the bonding pattern 211, the first electrode pattern 221 and the first semiconductor pattern 231 of the light-emitting device 260, so as to prevent the reflective layer 330 from electrically connecting first electrode patterns of adjacent light-emitting devices 260. The reflective layer 330 is configured to reflect the light emitted by the light-emitting device 260, such that the light emitted by the light-emitting device is directed as much as possible toward a coloring region 600 corresponding to the light-emitting device 260, which improves the light extraction efficiency of the light-emitting substrate 1100. Furthermore, the reflective layer may reduce the risk of the light being directed toward an adjacent light-emitting device 260, thereby reducing the risk of light mixing between adjacent light-emitting devices 260.

For example, a material of the insulating layer 320 may include an insulating material, such as silicon oxide. A thickness of the insulating layer 320 may be in a range of 500 nm to 1000 nm. For example, the thickness of the insulating layer 320 may be 500 nm, 750 nm, 900 nm or 1000 nm.

Referring to FIG. 11, FIG. 11 may be regarded as a bottom view of the light-emitting substrate 1100 shown in FIG. 7 with the driving backplane 100 removed. The third recess 310 include a plurality of first sub-recesses 311 and a plurality of second sub-recesses 312. The plurality of first sub-recesses 311 are arranged at intervals in a first direction X and all extend in a second direction Y. The plurality of second sub-recesses 312 are arranged at intervals in the second direction Y and all extend in the first direction X. The plurality of first sub-recesses 311 and the plurality of second sub-recesses 312 intersect with each other to constitute a grid structure, and each square in the grid structure defines a light-emitting device 260. A shape defined by each square may be substantially a shape of a light-emitting region of a light-emitting device 260. The first direction X intersects with the second direction Y; for example, the first direction X and the second direction Y are perpendicular to each other.

It will be understood that, as shown in FIG. 11, the light-emitting region of the light-emitting device 260 may be in a shape of a rectangle. Of course, the light-emitting region of the light-emitting device 260 may be in a shape of other polygons (e.g., triangle, hexagon or octagon), circle or ellipse or may be in any other desired shapes, which is not specifically limited in the embodiments of the present disclosure, as long as the same technical concept is adopted.

In some embodiments, with continued reference to FIG. 10, in a direction (a horizontal direction in FIG. 10) perpendicular to a sidewall of the third recess 310, two portions of the reflective layer 330 respectively covering two opposite sidewalls of the insulating layer 320 have a first gap D₁ therebetween. In this way, the thickness of the reflective layer 330 may be reduced, the material usage of the reflective layer 330 may be reduced, so that the manufacturing cost of the light-emitting substrate 1100 may be reduced.

For example, a material of the reflective layer 330 may include silver or aluminum. Of course, other metal or non-metal materials with high reflectivity may also be adopted as long as the same technical concept is adopted.

In some other embodiments, as shown in FIG. 12, the reflective layer 330 may completely fill the gaps of the insulating layer 320 in the direction perpendicular to the sidewall of the third recess 310; for example, in a case where a gap of the insulating layer 320 in the direction perpendicular to the sidewall of the third recess 310 is small (e.g., less than 1 μm), the reflective layer 330 may completely fill the gap of the insulating layer 320.

In some embodiments, as shown in FIG. 10, in the direction perpendicular to the sidewall of the third recess 310, a dimension of the third recess 310 is D₃, and the value of D₃ is in a range of 2 μm to 3 μm; that is, a spacing between two adjacent light-emitting devices 260 is in the range of 2 μm to 3 μm. As an example, the value of D₃ may be 2 μm, 2.3 μm, 2.5 μm, 2.9 μm or 3 μm, which will not be enumerated in the embodiments of the present disclosure. The thickness of the insulating layer 320 is in a range of 0.1 μm to 0.5 μm; for example, the thickness of the insulating layer 320 may be 0.1 μm, 0.3 μm, 0.4 μm or 0.5 μm, which will not be enumerated in the embodiments of the present disclosure. The thickness of the reflective layer 330 is in a range of 50 nm to 150 nm; for example, the thickness of the reflective layer 330 may be 50 nm, 80 nm, 100 nm, 135 nm or 150 nm, which will not be individually enumerated in the embodiments of the present disclosure. In the case where the value of D₃ is 2 μm, the thickness of the insulating layer 320 is less than 1000 nm, so that a gap for accommodating the reflective layer 330 may be formed between opposite sidewalls of the insulating layer 320.

In some embodiments, as shown in FIG. 10, an orthographic projection of the second electrode 400 on the driving backplane 100 is located in an orthographic projection of the isolation structure 300 on the driving backplane 100, so that an orthographic projection of a coloring region 600 on the driving backplane 100 covers an orthographic projection of a light-emitting device 260 corresponding to the coloring region 600 on the driving backplane 100. In this way, the light emitted by the light-emitting device 260 is directed as much as possible toward the coloring region 600 corresponding to the light-emitting device 260 and emitted after being color-converted by the color conversion layer in the coloring region 600, thereby improving the luminous efficiency of the light-emitting substrate 1100.

As shown in FIG. 10, in the direction perpendicular to the driving backplane 100, the second electrode 400 and the isolation structure 300 have a second gap D₂ therebetween, so that the second semiconductor layer 250 is continuous between the second electrode 400 and the isolation structure 300; that is, the second semiconductor layer 250 is prevented from being separated by the second electrode 400 and the isolation structure 300.

Referring to FIG. 3, the second electrode layer 400 includes a plurality of first sub-portions 410 and a plurality of second sub-portions 420. The plurality of first sub-portions are arranged at intervals in the first direction X and all extend in the second direction Y. The plurality of second sub-portions 420 are arranged at intervals in the second direction Y and all extend in the first direction X. The plurality of first sub-portions 410 and the plurality of second sub-portions 420 intersect with each other to constitute a grid structure, and each square in the grid structure defines a coloring region 600.

In some embodiments, referring to FIG. 3, in a row direction (the first direction X) in which the plurality of light-emitting devices 260 are arranged, a dimension of the light-emitting device 260 is D₄, and the value of D₄ is in a range of 3 μm to 5 μm, inclusive; in a column direction (the second direction Y) in which the plurality of light-emitting devices 260 are arranged, a dimension of the light-emitting device 260 is D₅, and the value of D₅ is in a range of 3 μm to 5 μm, inclusive. In this way, the arrangement density of the light-emitting devices 260 in the light-emitting substrate 1100 may be greatly increased, which increases the pixel density of the display apparatus 1000. A display apparatus with up to 5000 PPI may be manufactured by using the light-emitting substrate 1100 provided in the embodiments of the present disclosure.

It will be understood that, in some display apparatuses with low pixel density requirements, the dimension of the light-emitting device 260 may be adaptively increased as needed, or the spacing between adjacent light-emitting devices 260 may be adaptively increased as needed.

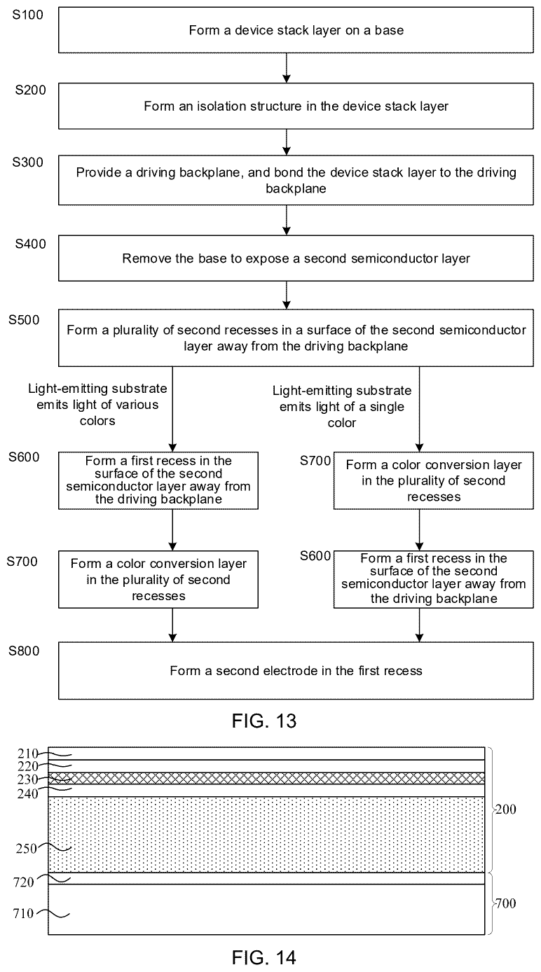

Some other embodiments of the present disclosure provide a manufacturing method of a light-emitting substrate. As shown in FIG. 13, the manufacturing method of the light-emitting substrate includes S100 to S800.

In S100, referring to FIG. 14, a device stack layer 200 is formed on a base 700.

The device stack layer 200 includes a second semiconductor layer 250, a light-emitting layer 240, a first semiconductor layer 230, a first electrode layer 220 and a bonding layer 210 that are sequentially arranged in a direction away from the base 700.

In some embodiments, the base 700 may include a substrate 710 and a buffer layer 720 disposed on the substrate 710. The substrate 710 may be one of a silicon (Si) substrate, a sapphire (aluminum oxide, Al₂O₃) substrate, a silicon carbide (SiC) substrate, gallium arsenide (GaAs), aluminum nitride (AlN), and zinc oxide (ZnO).

The buffer layer 720, the second semiconductor layer 250, the light-emitting layer 240 and the first semiconductor layer 230 may be sequentially grown on the substrate 710 with an epitaxial process. The second semiconductor layer 250, the light-emitting layer 240 and the first semiconductor layer 230 may also be referred to as epitaxial layers, and the base 700 and the epitaxial layers may together be referred to as an epitaxial wafer.

As an example, after the epitaxial wafer is formed, the first electrode layer 220 may be formed by evaporation or sputtering. As for the material and thickness of the first electrode layer 220, reference is made to the above description, which will not be repeated here. After the first electrode layer 220 is formed, a suitable process may be selected to form the bonding layer 210 based on the material used for the bonding layer 210. For example, in the case where the material of the bonding layer 210 is MTD or copper, the bonding layer 210 may be formed by sputtering; and in the case where the material of the bonding layer 210 is gold, the bonding layer 210 may be formed by evaporation. As for the thickness of the bonding layer 210, reference is made to the above description, which will not be repeated here.

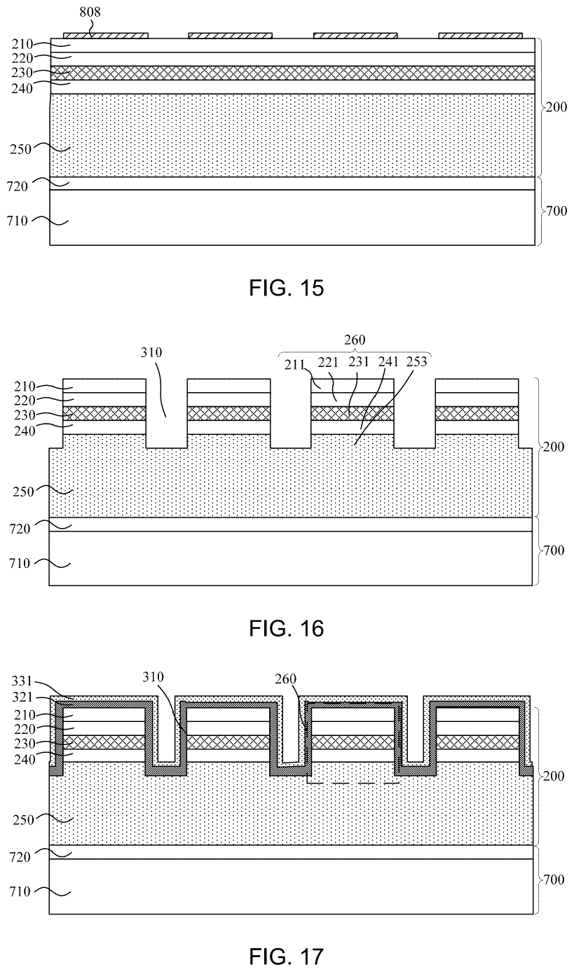

In S200, referring to FIGS. 15 to 19, an isolation structure 300 is formed in the device stack layer 200.

The isolation structure 300 penetrates the bonding layer 210, the first electrode layer 220, the first semiconductor layer 230 and the light-emitting layer 240, and extends into the second semiconductor layer 250. The isolation structure 300 separates the device stack layer 200 into a plurality of light-emitting devices 260. Each light-emitting device 260 may include a bonding pattern 211 located in the bonding layer 210, a first electrode pattern 221 located in the first electrode layer 220, a first semiconductor pattern 231 located in the first semiconductor layer 230, a light-emitting pattern 241 located in the light-emitting layer 240, and a second semiconductor pattern 253 located in the second semiconductor layer 250.

In some embodiments, S200 in which the isolation structure 300 is formed in the device stack layer 200 may include S210 and S220.

In S210, a third recess 310 is formed in the device stack layer 200.

The third recess 310 penetrates the bonding layer 210, the first electrode layer 220, the first semiconductor layer 230 and the light-emitting layer 240, and extends into the second semiconductor layer 250. The third recess 310 separates the device stack layer 200 into the plurality of light-emitting devices 260.

For example, S210 in which the third recesses 310 are formed in the device stack layer 200 may include S211 and S212.

In S211, referring to FIG. 15, an eighth mask layer 808 is formed on a surface of the bonding layer 210 by using a photolithography process.

For example, the photolithography process may include, but is not limited to, photoresist coating, exposure and development, and etching.

In S212, referring to FIG. 16, the bonding layer 210, the first electrode layer 220, the first semiconductor layer 230, the light-emitting layer 240 and the second semiconductor layer 250 are etched in steps by using the eighth mask layer 808 as a mask, and the eighth mask layer 808 is removed.

For example, an ion beam etching (IBE) process may be used to etch the bonding layer 210 and the first electrode layer 220. Then, an inductively coupled plasma (ICP) etching technique is used to etch the first semiconductor layer 230, the light-emitting layer 240 and the second semiconductor layer 250. The etching gas may include chlorine gas (Cl₂) and boron trichloride (BCl₃).

In S220, referring to FIGS. 17 to 19, an insulating layer 320 and a reflective layer 330 are sequentially formed on sidewalls and bottomwalls of the third recess 310.

The insulating layer 320 covers the sidewalls and the bottomwalls of the recess 310 and exposes a surface of the bonding layer 210 away from the base 700. The reflective layer 330 covers a surface of the insulating layer 320 away from the sidewalls and the bottomwalls of the third recess 310, and exposes a surface (the surface of the bonding layer 210 away from the base 700) of the device stack layer 200 away from the base 700. The insulating layer 320 and the reflective layer 330 do not cover the surface of the bonding layer 210 away from the base 700, which facilitates bonding of the bonding layer 210 to the driving backplane 100 in a subsequent process. As for the materials of the insulating layer 320 and the reflective layer 330 and the thicknesses of the insulating layer 320 and the reflective layer 330, reference is made to the above description, which will not be repeated here.

For example, S220 in which the insulating layer 320 and the reflective layer 330 are sequentially formed on the sidewalls and the bottomwalls of the third recess 310 includes S221 to S223.

In S221, as shown in FIG. 17, an initial insulating layer 321 and an initial reflective layer 331 are sequentially formed on the device stack layer 200. The initial insulating layer 321 covers the sidewalls and the bottomwalls of the third recess 310, and covers the surface of the bonding layer 210 away from the base 700; that is, the initial insulating layer 321 is of a continuous whole layer structure. The initial reflective layer 331 covers a surface of the initial insulating layer 321; that is, the initial reflective layer 331 is also of a continuous whole layer structure.

For example, the initial insulating layer 321 may be formed by chemical vapor deposition (CVD), physical vapor deposition (PVD), atomic layer deposition (ALD) or any other thin film deposition processes. The initial reflective layer is formed by evaporation, sputtering or other processes.

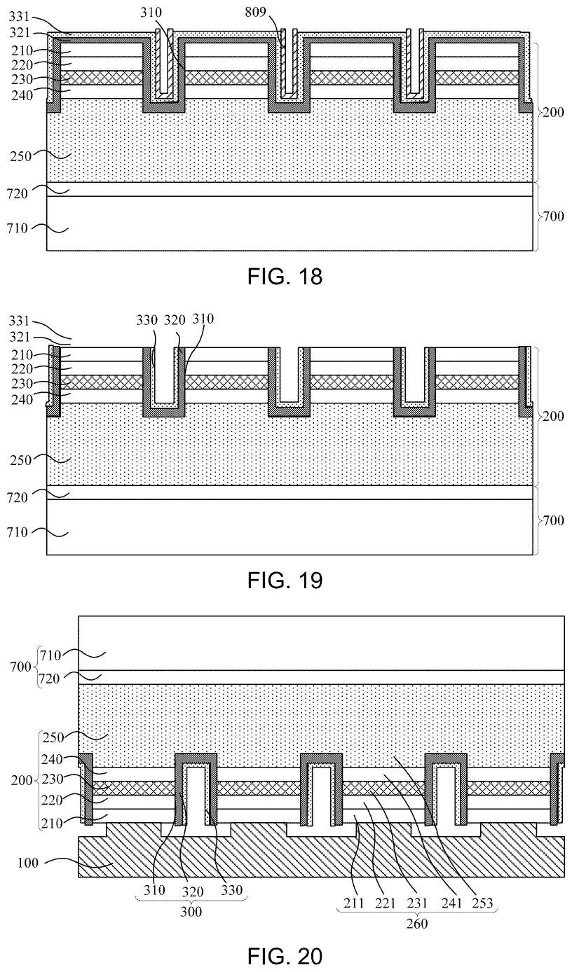

In S222, referring to FIG. 18, a ninth mask layer 809 is formed on a side of the initial reflective layer 331 away from the base 700. The ninth mask layer 809 exposes portions of the initial reflective layer 331 located on the surface of the bonding layer 210 away from the base 700.

For example, a whole layer of an initial ninth mask layer may be formed by CVD, PVD, ALD or any other thin film deposition processes, and then the initial ninth mask layer may be patterned by an etching process to expose the portions of the initial reflective layer 331 located on the surface of the bonding layer 210 away from the base 700.

In S223, referring to FIG. 19, portions of the initial reflective layer 331 and the initial insulating layer 321 covering the surface of the bonding layer 210 away from the base 700 are removed by using the ninth mask layer 809 as a mask, and the ninth mask layer 809 is removed.

One of the initial reflective layer 331 and the initial insulating layer 321 is made of a metal material, and the other is made of an insulating material. As an example, the initial reflective layer 331 and the initial insulating layer 321 may be etched in steps; for example, the initial reflective layer 331 may be etched by an IBE process, and the initial insulating layer 321 may be etched by a dry etching process or a wet etching process.

After the portions of the initial reflective layer 331 covering the surface of the bonding layer 210 away from the base 700 are removed, the initial reflective layer 331 is formed as the reflective layer 330. After the portions of the initial insulating layer 321 covering the surface of the bonding layer 210 away from the base 700 are removed, the initial insulating layer 321 becomes the insulating layer 320. The third recess 310, the insulating layer 320 and the reflective layer 330 together constitute the isolation structure 300. The isolation structure 300 separates the device stack layer 200 into the plurality of light-emitting devices 260.

In S300, referring to FIG. 20, a driving backplane 100 is provided, and the device stack layer 200 is bonded to the driving backplane 100.

The driving backplane 100 includes a plurality of driving circuits, the bonding layer 210 of the device stack layer 200 is bonded to the driving backplane 100, and a light-emitting device 260 is connected to a driving circuit. A bonding pattern 211 of a light-emitting device 260 is connected to a driving circuit, and the driving circuit is connected to a first semiconductor pattern 231 sequentially through the bonding pattern 211 and a first electrode pattern 221, and is configured to apply a voltage to the first semiconductor pattern 231.

As an example, the device stack layer 200 (along with the base 700) is flipped over, and the device stack layer 200 is bonded to the driving backplane 100 by a high-precision alignment bonding process. In the driving backplane 100, the film layer bonded to the bonding layer 210 may be a metal film layer, such as a tin layer or a gold layer.

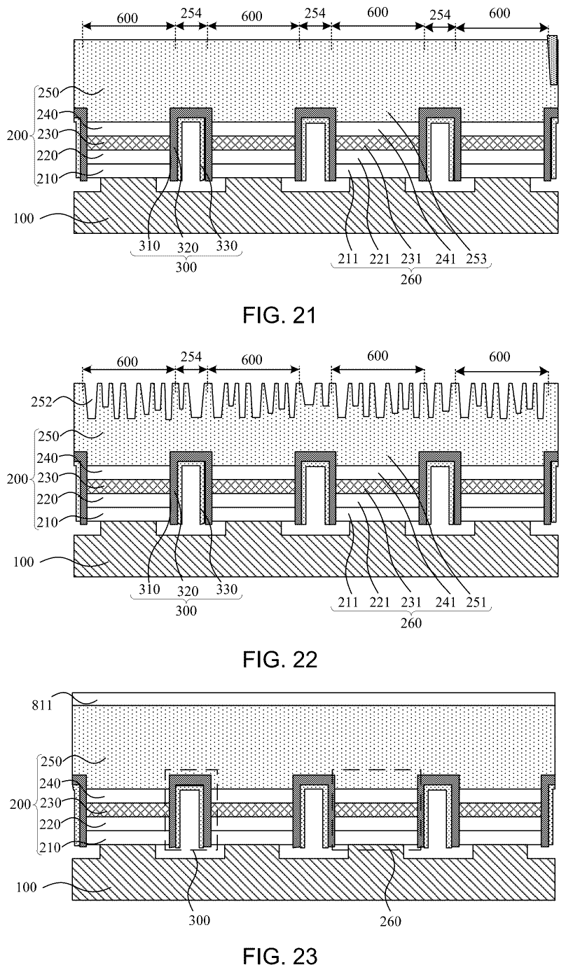

In S400, referring to FIG. 21, the base 700 is removed to expose the second semiconductor layer 250.

For example, in the case where the substrate 710 is a sapphire substrate, the sapphire substrate may be removed by using a laser lift-off (LLO) technique; in the case where the substrate 710 is a silicon substrate, the thickness of the substrate 710 may be reduced firstly by a chemical-mechanical polishing (CMP) process, and then the remaining substrate 710 may be removed by a wet etching process. The buffer layer 720 may be removed by using an ICP etching technique, and the etching gas may include chlorine gas (Cl₂) and boron trichloride (BCl₃).

The second semiconductor layer 250 includes a plurality of coloring regions 600 arranged in an array, and any adjacent coloring regions 600 have an isolation region 254 therebetween. The isolation region 254 refers to a region for forming first recess 251.

In S500, referring to FIGS. 22 to 27, a plurality of second recesses 252 are formed in a surface (the upper surface of the second semiconductor layer 250 in these figures) of the second semiconductor layer 250 away from the driving backplane 100.

A part of the plurality of second recesses 252 is located in the plurality of coloring regions 600, and the other part of the plurality of second recesses 252 is located in the isolation regions 254; that is, the plurality of second recesses 252 are distributed in the entire region of the second semiconductor layer 250.

In some embodiments, S500 in which the plurality of second recesses 252 are formed in the surface of the second semiconductor layer 250 away from the driving backplane 100 includes S510.

In S510, referring to FIG. 22, the second semiconductor layer 250 is etched by using an electrochemical etching process to form the plurality of second recesses 252 in the surface of the second semiconductor layer 250 away from the driving backplane 100.

By using the electrochemical etching process, the second recess 252 with a small opening may be formed, which can improve the distribution density of the second recesses 252. In addition, for the electrochemical etching process, the operation and manufacturing process are simple, which is conducive to reducing the manufacturing cost of the light-emitting substrate. Moreover, the opening shapes of the plurality of second recesses 252 obtained by electrochemical etching are irregular, and the sizes of the plurality of second recesses 252 are uncertain. As a result, among the plurality of second recesses 252, at least two second recesses 252 have different opening sizes, and/or at least two second recesses 252 have different opening shapes, and/or at least two second recesses 252 have different depths in the direction (the vertical direction in FIG. 22) perpendicular to the second semiconductor layer 250.

In some other embodiments, referring to FIGS. 23 to 27, S500 in which the plurality of second recesses 252 are formed in the surface of the second semiconductor layer 250 away from the driving backplane 100 includes S521 to S525.

In S521, referring to FIG. 23, an initial mask layer 811 is formed on the second semiconductor layer 250.

The initial mask layer 811 covers the surface of the second semiconductor layer 250 away from the driving backplane 100. A material of the initial mask layer 811 may be silicon oxide (SiO). For example, the initial mask layer 811 may be formed by plasma enhanced chemical vapor deposition (PECVD), CVD, PVD, ALD or any other thin film deposition processes.

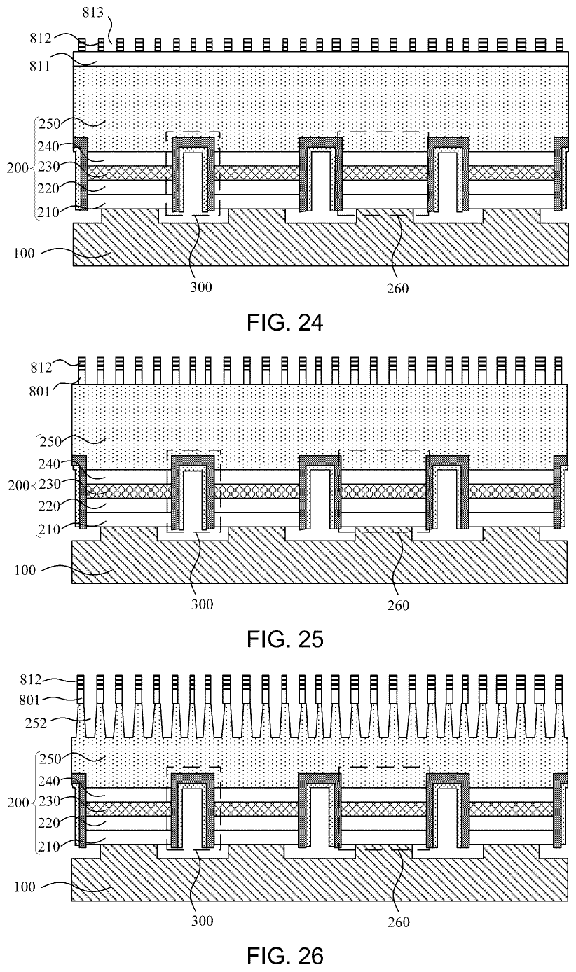

In S522, referring to FIG. 24, an imprint pattern layer 812 is formed on the initial mask layer 811.

The imprint pattern layer 812 includes a plurality of imprint patterns 813, and an imprint pattern 813 exposes a portion of the initial mask layer 811. The imprint pattern 813 is, for example, a through hole. For example, the imprint pattern layer 812 may be formed by using a nanoimprint technique.

In S523, referring to FIG. 25, the initial mask layer 811 is etched to form (such that the initial mask layer 811 is formed into) a first mask layer 801 by using the imprint pattern layer 812 as a mask.

The first mask layer 801 has the same pattern as the imprint pattern layer 812. For example, the initial mask layer 811 may be etched by a dry or wet etching process, which is not specifically limited here.

In S524, referring to FIG. 26, the second semiconductor layer 250 is etched by using the first mask layer 801 as a mask to form the plurality of second recesses 252 in the second semiconductor layer 250.

For example, the second semiconductor layer 250 may be etched by a dry etching process or a wet etching process. The above step S523 and step S524 may be completed synchronously; that is, the initial mask layer 811 and the second semiconductor layer 250 may be successively etched in a single etching process. Alternatively, the above step S523 and step S524 may be completed in steps; that is, the initial mask layer 811 is etched by an etching process to form the first mask layer 801, and then the second semiconductor layer 250 is etched by another etching process to form the plurality of second recesses 252 in the second semiconductor layer 250.

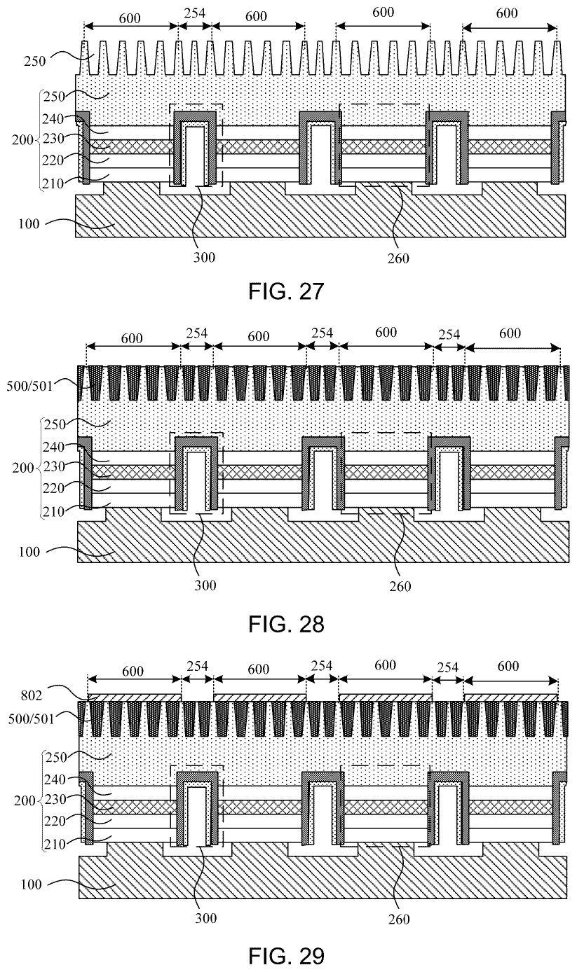

In S525, referring to FIG. 27, the imprint pattern layer 812 and the first mask layer 801 are removed.

The structures of the plurality of second recesses 252 formed through the above steps S521 to S525 are substantially the same; that is, the plurality of second recesses 252 have substantially the same the opening sizes, substantially the same opening shapes and substantially the same dimensions in the direction perpendicular to the second semiconductor layer 250 (the vertical direction in FIG. 26). Referring to FIG. 27, the plurality of second recesses 252 may be evenly distributed in the coloring regions 600 and the isolation regions 254.

Other steps in the manufacturing method of the light-emitting substrate in some embodiments of the present application will be exemplarily described below by taking an example in which the plurality of second recesses 252 are formed in the surface of the second semiconductor layer 250 away from the driving backplane 100 through the above steps S521 to S525, but the embodiments of the present disclosure are not limited thereto, as long as the same technical concept is adopted.

The light-emitting substrate may be a single-color light-emitting substrate emitting light of a single color, or the light-emitting substrate may be a color light-emitting substrate emitting light of multiple colors or a full-color light-emitting substrate.

In the case where the light-emitting substrate is a single-color light-emitting substrate emitting light of a single color, after the step S500 in which the plurality of second recesses 252 are formed in the surface of the second semiconductor layer 250 away from the driving backplane 100, the manufacturing method includes S700 and S600, and S700 is performed before S600. Before S700 is performed, whether S570 is performed may be determined according to actual needs.

In S570, the plurality of second recesses 252 are surface-treated to increase adhesion between a material of a color conversion layer 500 and the second recesses 252.

For example, in the case where the material of the color conversion layer is filled in the second recesses 252 poorly due to poor adhesion of the material of the color conversion layer 500 to the surfaces of the second recesses 252, the above S570 may be performed before S700.

For example, a preset solution may be used to soak the second recesses 252; an electrostatic adsorption force of the preset solution is opposite to an electrostatic adsorption force of the material of the color conversion layer, so that the surfaces of the second recesses 252 may have an electrostatic adsorption force electrically opposite to the electrostatic adsorption force of the material of the color conversion layer. In this way, the electrostatic adsorption force between the material of the color conversion layer and the surfaces of the second recesses 252 is increased, which enhances the effect of filling the second recesses 252 with the material of the color conversion layer and facilitates the filling of the second recesses 252 with the material of the color conversion layer.

In S700, referring to FIG. 28, the color conversion layer 500 is formed in the plurality of second recesses 252.

In some embodiments, it is possible to use a color conversion layer primary liquid to form the color conversion layer 500 in the second recesses 252 by spin coating, drop coating or immersion. The color conversion layer primary liquid refers to a liquid containing the material of the color conversion layer; for example, in the case where the material of the color conversion layer 500 includes quantum dots, the color conversion layer primary liquid may be a solution formed by a quantum dot material and toluene or other organic solvents. A color conversion block 501 is formed in each second recess 252. The light-emitting substrate emits light of a single color, so that the materials in different coloring regions 600 may be the same, and thus the color conversion layer 500 made of the same material may be formed in all the second recesses 252 simultaneously.

In S600, referring to FIGS. 29 to 31, a first recess 251 is formed in the surface of the second semiconductor layer 250 away from the driving backplane 100.

The first recess 251 is located in the isolation regions 254, and the first recess 251 is used to separate the plurality of coloring regions 600 in the second semiconductor layer 250 from each other. For example, S600 in which the first recess 251 is formed in the surface of the second semiconductor layer 250 away from the driving backplane 100 includes S611 to S613.

In S611, referring to FIG. 29, a second mask layer 802 is formed on the surface of the second semiconductor layer 250 away from the driving backplane 100.

The second mask layer 802 covers the plurality of coloring regions 600 and exposes the isolation regions 254. As an example, the second mask layer 802 may be formed by a photolithography process or other suitable processes, as long as the same technical concept is adopted.

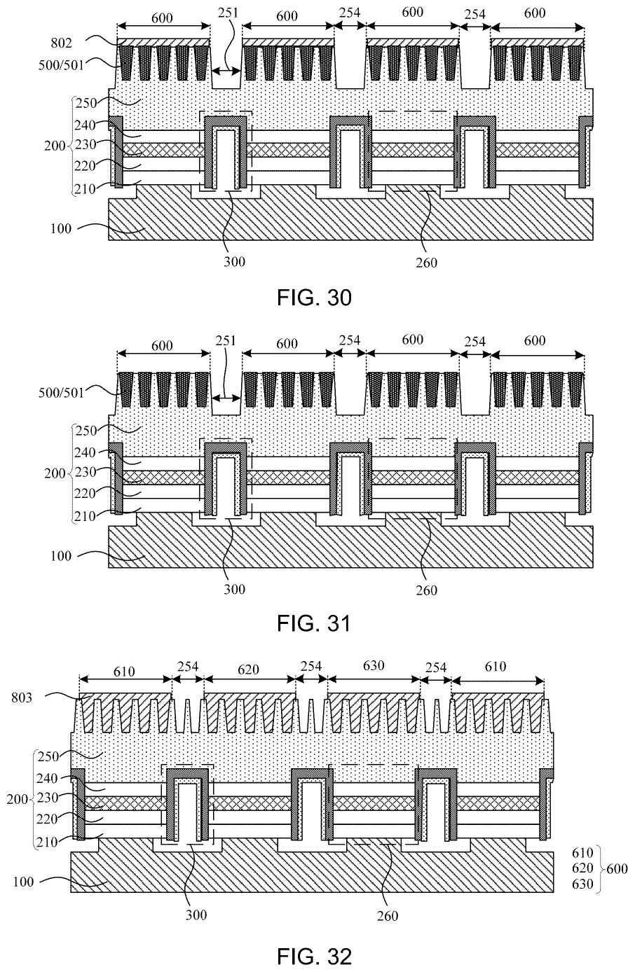

In S612, referring to FIG. 30, portions of the second semiconductor layer 250 and the color conversion layer 500 located in the isolation regions 254 are removed by using the second mask layer 802 as a mask to form the first recess 251.

For example, it is possible to use a dry etching process to remove the portions of the second semiconductor layer 250 and the color conversion layer 500 located in the isolation regions 254. The dry etching process may be, for example, an ICP process or an IBE process. As for the size and other characteristics of the first recess 251, reference is made to the above description, which will not be repeated here.

In S613, referring to FIG. 31, the second mask layer 802 is removed.

In some other embodiments, as shown in FIG. 7, in the case where the light-emitting substrate 1100 is a color light-emitting substrate emitting light of various colors, the color conversion layer 500 includes a plurality of first color conversion portions 510, a plurality of second color conversion portions 520, and a plurality of third color conversion portions 530. The plurality of first color conversion portions 510 are configured to convert light emitted by some light-emitting devices 260 into a first color, the plurality of second color conversion portions 520 are configured to convert light emitted by some light-emitting devices 260 into a second color, and the plurality of third color conversion portions 530 are configured to convert light emitted by some light-emitting devices 260 into a third color. As an example, the first color, the second color, and the third color may be red, green, and blue, respectively, so that the light-emitting substrate 1100 can achieve full-color display.

In the case where the light-emitting substrate 1100 is a color light-emitting substrate emitting light of various colors, after S500 in which the plurality of second recesses 252 are formed in the surface of the second semiconductor layer 250 away from the driving backplane 100, the manufacturing method includes S600 and S700, and S600 is performed before S700.

In S600, referring to FIGS. 32 to 34, a first recess 251 is formed in the surface of the second semiconductor layer 250 away from the driving backplane 100.

The first recess 251 is located in the isolation regions 254, and the first recess 251 is used to separate the plurality of coloring regions 600 in the second semiconductor layer 250 from each other. For example, S600 in which the first recess 251 is formed in the surface of the second semiconductor layer 250 away from the driving backplane 100 includes S621 to S623.

In S621, referring to FIG. 32, a third mask layer 803 is formed on the surface of the second semiconductor layer 250 away from the driving backplane 100.

The third mask layer 803 covers the plurality of coloring regions 600 and exposes the isolation regions 254. For example, the third mask layer 803 may be formed by a photolithography process or other suitable processes, as long as the same technical concept is adopted.

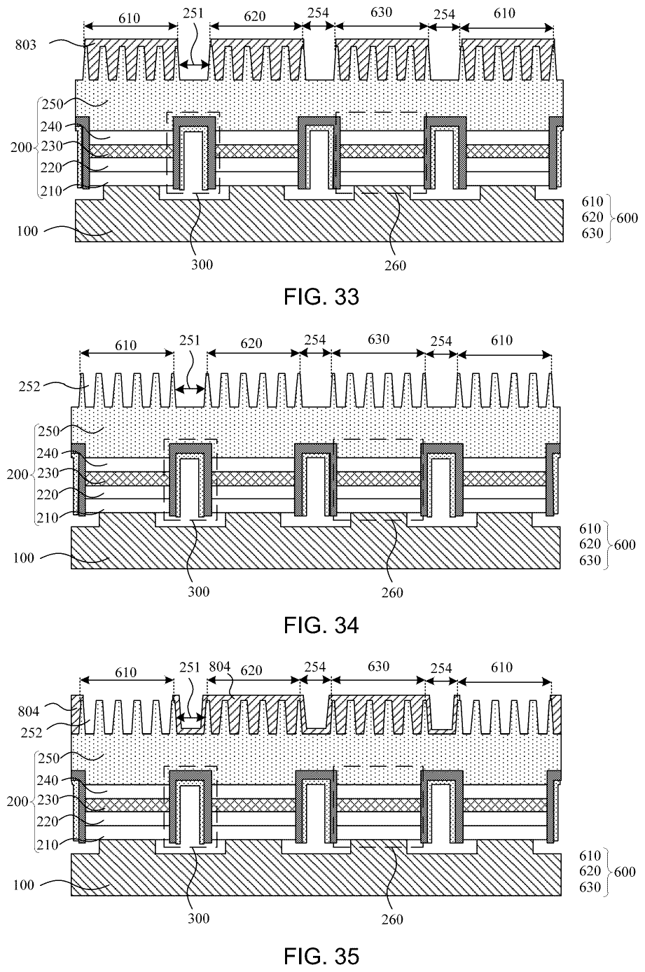

In S622, referring to FIG. 33, portions of the second semiconductor layer 250 located in the isolation regions 254 are removed by using the third mask layer 803 as a mask to form the first recess 251.

For example, it is possible to use a dry etching process to remove the portions of the second semiconductor layer 250 located in the isolation regions 254. The dry etching process may be, for example, an ICP process or an IBE process. As for the size and other characteristics of the first recess 251, the reference is made to the above description, which will not be repeated here.

In S623, referring to FIG. 34, the third mask layer 803 is removed.

In some embodiments, after S623 in which the third mask layer 803 is removed and before S700, the manufacturing method of the light-emitting substrate may further include step S570 according to actual needs.

In S570, the plurality of second recesses 252 are surface-treated to increase adhesion between the material of the color conversion layer 500 and the second recesses 252.

For example, in the case where the material of the color conversion layer is filled in the second recesses 252 poorly due to poor adhesion of the material of the color conversion layer 500 to the surfaces of the second recesses 252, the above S570 may be performed before S700.

For example, a preset solution may be used to soak the second recesses 252; an electrostatic adsorption force of the preset solution is opposite to an electrostatic adsorption force of the material of the color conversion layer, so that the surfaces of the second recesses 252 may have an electrostatic adsorption force electrically opposite to the electrostatic adsorption force of the material of the color conversion layer. In this way, the electrostatic adsorption force between the material of the color conversion layer and the surfaces of the second recesses 252 is increased, which enhances the effect of filling the second recesses 252 with the material of the color conversion layer and facilitates the filling of the second recesses 252 with the material of the color conversion layer.

In S700, referring to FIGS. 35 to 43, the color conversion layer 500 is formed in the plurality of second recesses 252.

On the basis that the light-emitting substrate 1100 is a color light-emitting substrate emitting light of various colors, the manufacturing method of the light-emitting substrate in the embodiments of the present disclosure will be exemplarily described below by taking an example in which the light-emitting substrate 1100 emits light of three colors; however, the embodiments of the present disclosure are not limited thereto, and the light-emitting substrate 1100 may also emit light of any other number of colors as long as the same technical concept is adopted.

In the case where the light-emitting substrate 1100 emits light of three colors, the plurality of coloring regions 600 may include a plurality of first coloring regions 610, a plurality of second coloring regions 620, and a plurality of third coloring regions 630. S700 in which the color conversion layer 500 is formed in the plurality of second recesses 252 may include S721 to S729.

In S721, referring to FIG. 35, a fourth mask layer 804 is formed on a side of the second semiconductor layer 250 away from the driving backplane 100. The fourth mask layer 804 covers the first recess 251, the plurality of second coloring regions 620 and the plurality of third coloring regions 630, and exposes the plurality of first coloring regions 610.

For example, the fourth mask layer 804 may be formed by a photolithography process or other suitable processes, which is not specifically limited in the embodiments of the present disclosure.

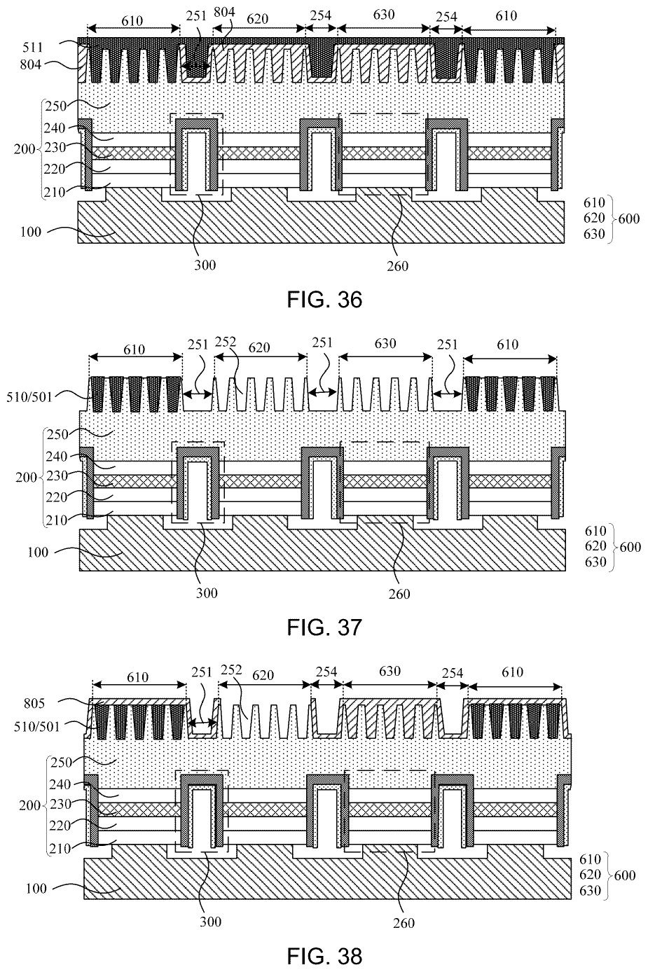

In S722, referring to FIG. 36, a first color conversion layer 511 is formed on a surface of the fourth mask layer 804 away from the driving backplane 100 and in second recesses 252 in the first coloring regions 610.

In some embodiments, it is possible to use a color conversion layer primary liquid to form the first color conversion layer 511 on the surface of the fourth mask layer 804 away from the driving backplane 100 and in the second recesses 252 in the first coloring regions 610 by spin coating, drop coating or immersion. A color conversion block is formed in each second recess 252 in the first coloring region 610. The first color conversion layer 511 is configured to convert light emitted by a light-emitting device 260 into a first color.

In S723, referring to FIG. 37, as shown in FIG. 37, the fourth mask layer 804 is removed, and a portion of the first color conversion layer 511 located on the surface of the fourth mask layer 804 away from the driving backplane 100 is removed.

The remaining portions (located in the first coloring regions 610) of the first color conversion layer 511 are formed as a plurality of first color conversion portions 510. As an example, the portion of the first color conversion layer 511 and the fourth mask layer 804 may be removed by a CMP process, a dry etching process or a wet etching process; alternatively, the fourth mask layer 804 may be directly removed by a lift-off process, and in the process of removing the fourth mask layer 804, the first color conversion layer 511 on the surface of the fourth mask layer 804 may be removed simultaneously, the embodiments of the present disclosure are not limited thereto, as long as the same technical concept is adopted.

In S724, referring to FIG. 38, a fifth mask layer 805 is formed on the side of the second semiconductor layer 250 away from the driving backplane 100.

The fifth mask layer 805 covers the first recess 251, the plurality of first coloring regions 610 and the plurality of third coloring regions 630, and exposes the plurality of second coloring regions 620. For example, the fifth mask layer 805 may be formed by a photolithography process or other suitable processes, which is not specifically limited here.

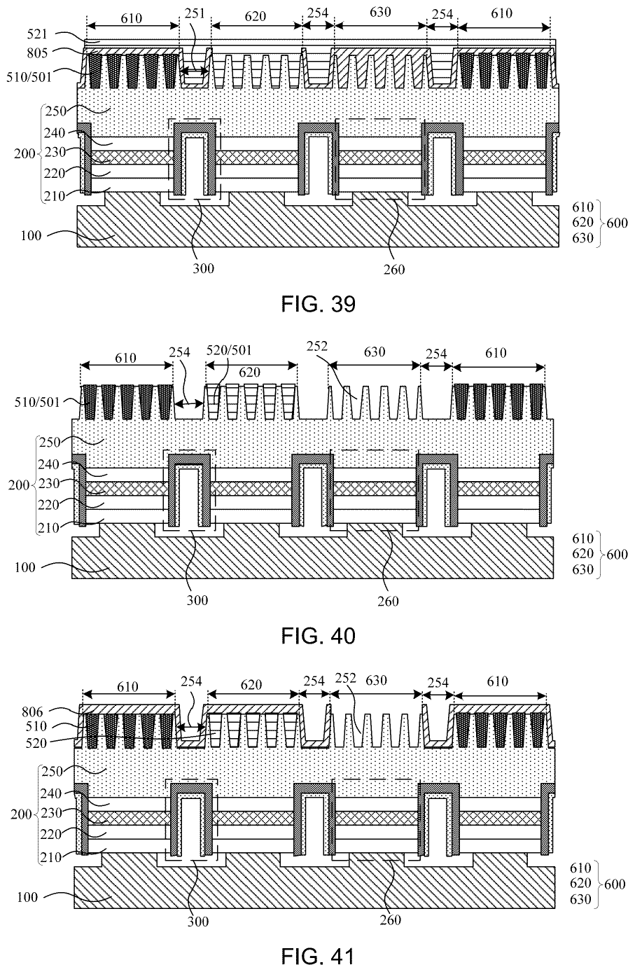

In S725, referring to FIG. 39, a second color conversion layer 521 is formed on a surface of the fifth mask layer 805 away from the driving backplane 100 and in the second coloring regions 620.

In some embodiments, it is possible to use a color conversion layer primary liquid to form the second color conversion layer 521 on the surface of the fifth mask layer 805 away from the driving backplane 100 and in second recesses 252 in the second coloring regions 620 by spin coating, drop coating or immersion. A color conversion block is formed in each second recess 252 in the second coloring region 620. The second color conversion layer 521 is configured to convert light emitted by the light-emitting devices 260 into a second color.

In S726, referring to FIG. 40, the fifth mask layer 805 is removed, and a portion of the second color conversion layer 521 located on the surface of the fifth mask layer 805 away from the driving backplane 100 is removed.

The remaining portions (located in the second coloring regions 620) of the second color conversion layer 521 are formed as the plurality of second color conversion portions 520. As an example, the portion of the second color conversion layer 521 and the fifth mask layer 805 may be removed by a CMP process, a dry etching process or a wet etching process; alternatively, the fifth mask layer 805 may be directly removed by a lift-off process, and in the process of removing the fifth mask layer 805, the second color conversion layer 521 on the surface of the fifth mask layer 805 may be removed simultaneously. The embodiments of the present disclosure are not limited thereto, as long as the same technical concept is adopted.

In S727, referring to FIG. 41, a sixth mask layer 806 is formed on the side of the second semiconductor layer 250 away from the driving backplane 100.

The sixth mask layer 806 covers the first recess 251, the plurality of first coloring regions 610 and the plurality of second coloring regions 620, and exposes the plurality of third coloring regions 630. For example, the fifth mask layer 805 may be formed by a photolithography process or other suitable processes, which is not specifically limited here.

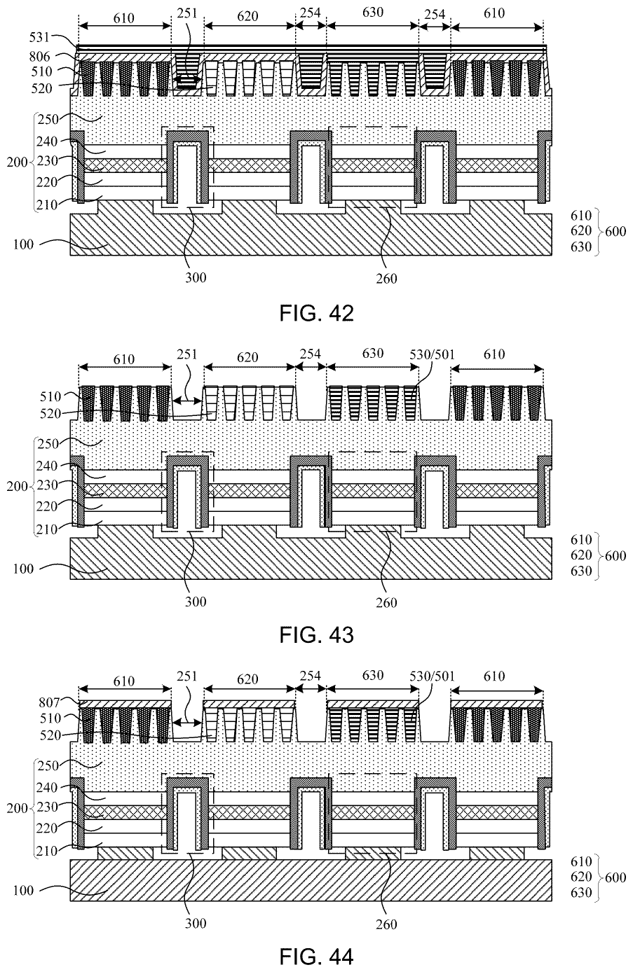

In S728, referring to FIG. 42, a third color conversion layer 531 is formed on a surface of the sixth mask layer 806 away from the driving backplane 100 and in the third coloring regions 630.

In some embodiments, it is possible to use a color conversion layer primary liquid to form the third color conversion layer 531 on the surface of the sixth mask layer 806 away from the driving backplane 100 and in second recesses 252 in the third coloring regions 630 by spin coating, drop coating or immersion. A color conversion block is formed in each second recess 252 in the third coloring region 630. The third color conversion layer 531 is configured to convert light emitted by the light-emitting devices 260 into a third color.

In S729, referring to FIG. 43, the sixth mask layer 806 is removed, and a portion of the third color conversion layer 531 located on a surface of the sixth mask layer 806 away from the driving backplane 100 is removed.

The remaining portions (located in the third coloring regions 630) of the third color conversion layer 531 are formed as a plurality of third color conversion portions 530. As an example, the portion of the third color conversion layer 531 and the sixth mask layer 806 may be removed by a CMP process, a dry etching process or a wet etching process; alternatively, the sixth mask layer 806 may be directly removed by a lift-off process, and in the process of removing the sixth mask layer 806, the third color conversion layer 531 on the surface of the sixth mask layer 806 may be removed simultaneously, and the embodiments of the present disclosure are not limited thereto, as long as the same technical concept is adopted.

In the case where the light-emitting substrate is a single-color light-emitting substrate emitting light of a single color, after S613 in which the second mask layer 802 is removed, the manufacturing method further includes S800. Alternatively, in the case where the light-emitting substrate is a color light-emitting substrate emitting light of various colors, after S729 in which the sixth mask layer 806 and the portion of the third color conversion layer 531 located on the surface of the sixth mask layer 806 away from the driving backplane 100 are removed, the manufacturing method further includes S800.

In S800, referring to FIGS. 44 to 46, a second electrode 400 is formed in the first recess 251.

At least a portion of the second electrode 400 is disposed in the first recess 251, and the second electrode 400 is connected to the second semiconductor layer 250, so that a voltage may be applied to the second semiconductor layer 250 through the second electrode 400. For example, the second electrode 400 may be partially located in the first recess 251 and partially extend out of the first recess 251, so that an end portion of the second electrode 400 away from the driving backplane 100 extends out of an end portion of the color conversion layer 500 away from the driving backplane 100.

In some embodiments, the second electrode 400 may be formed by a metal lift-off process. As an example, S800 in which the second electrode 400 is formed in the first recess 251 may include S810 to S830.

In S810, referring to FIG. 44, a seventh mask layer 807 is formed on the side of the second semiconductor layer 250 away from the driving backplane 100. The seventh mask layer 807 covers the plurality of coloring regions 600 and exposes the first recess 251.

For example, the third mask layer 803 may be formed by a photolithography process or other suitable processes, which is not specifically limited in the embodiments of the present disclosure.

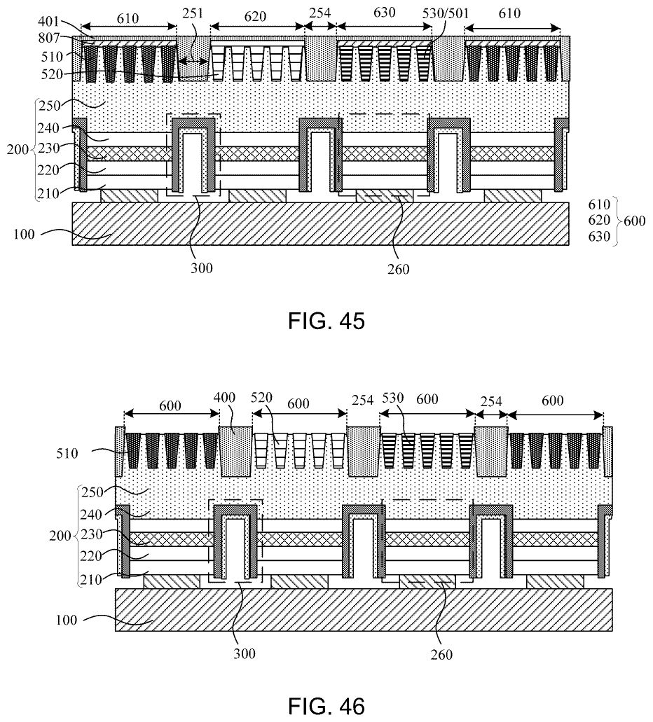

In S820, referring to FIG. 45, a second electrode layer 401 is formed on a surface of the seventh mask layer away from the driving backplane and in the first recess 251.

The second electrode layer 401 covers the first recess 251 and the surface of the seventh mask layer 807. For example, the second electrode layer 401 may be formed by evaporation, sputtering or other processes. As for the material and thickness of the second electrode layer 401, reference is made to the above description, which will not be repeated here.

In S830, referring to FIG. 46, the seventh mask layer 807 is removed, and a portion of the second electrode layer 401 located on the surface of the seventh mask layer 807 is removed.

After the portion of the second electrode layer 401 located on the surface of the seventh mask layer 807 is removed, the remaining portion of the second electrode layer 401 located in the first recess 251 becomes the second electrode 400.

The above are merely specific implementations of the present disclosure, but the protection scope of the present disclosure is not limited thereto, and variations or substitutions that any person skilled in the art could conceive of within the technical scope of the present disclosure should be included in the protection scope of the present disclosure. Therefore, the protection scope of the present disclosure should be subject to the protection scope of the claims.

What is claimed is:

1. A light-emitting substrate, comprising:
a driving backplane including a plurality of driving circuits;
a device stack layer including a bonding layer, a first electrode layer, a first semiconductor layer, a light-emitting layer, and a second semiconductor layer that are stacked in a direction away from the driving backplane, wherein the bonding layer is bonded to the driving backplane, a surface of the second semiconductor layer away from the driving backplane is provided with a first recess therein, the first recess separates the second semiconductor layer into a plurality of coloring regions, and at least one coloring region is provided with a plurality of second recesses therein;
an isolation structure penetrating the bonding layer, the first electrode layer, the first semiconductor layer, and the light-emitting layer and extending into the second semiconductor layer in a direction perpendicular to the driving backplane and away from the driving backplane, wherein the isolation structure separates the device stack layer into a plurality of light-emitting devices;
a second electrode at least partially disposed in the first recess; and
a color conversion layer at least partially disposed in the plurality of second recesses;
wherein a light-emitting device of the plurality of light-emitting devices corresponds to a coloring region of the plurality of coloring regions, an orthographic projection of the coloring region on the driving backplane at least partially overlaps with an orthographic projection of the light-emitting device corresponding to the coloring region on the driving backplane, and the light-emitting device is connected to a driving circuit of the plurality of driving circuits.

2. The light-emitting substrate according to claim 1, wherein the plurality of second recesses are arranged in an array, and the plurality of second recesses have substantially a same structure.

3. The light-emitting substrate according to claim 1, wherein
in the plurality of second recesses, at least two second recesses have different opening sizes, and/or
at least two second recesses have different opening shapes, and/or
at least two second recesses have different depths in a direction perpendicular to the second semiconductor layer.

4. The light-emitting substrate according to claim 1, wherein the plurality of coloring regions include a plurality of first coloring regions, a plurality of second coloring regions and a plurality of third coloring regions; and
the color conversion layer includes:
a plurality of first color conversion portions, a first color conversion portion being disposed in a first coloring region, and the first color conversion portion being configured to convert light emitted by a light-emitting device into a first color;
a plurality of second color conversion portions, a second color conversion portion being disposed in a second coloring region, and the second color conversion portion being configured to convert light emitted by another light-emitting device into a second color; and
a plurality of third color conversion portions, a third color conversion portion being disposed in a third coloring region, and the third color conversion portion being configured to convert light emitted by yet another light-emitting device into a third color.

5. The light-emitting substrate according to claim 1, wherein the color conversion layer includes a plurality of fourth color conversion portions, a fourth color conversion portion is disposed in a plurality of second recesses of the coloring region, and the plurality of fourth color conversion portions are configured to convert light emitted by the plurality of light-emitting devices into a fourth color.

6. The light-emitting substrate according to claim 1, wherein a material of the second electrode includes a reflective material.

7. The light-emitting substrate according to claim 6, wherein in a direction perpendicular to the driving backplane and approaching the driving backplane, an end of the second electrode proximate to the driving backplane extends out of an end of the color conversion layer proximate to the driving backplane, and/or in the direction perpendicular to the driving backplane and away from the driving backplane, an end of the second electrode away from the driving backplane extends out of an end of the color conversion layer away from the driving backplane.

8. The light-emitting substrate according to claim 6, wherein the second electrode includes:
a stacked layer structure, wherein the stacked layer structure includes a titanium layer, an aluminum layer, a nickel layer, and a gold layer that are stacked in the direction away from the driving backplane, or the stacked layer structure includes a chromium layer, a platinum layer, and a gold layer that are stacked in the direction away from the driving backplane; and
a pad layer structure disposed on a side of the stacked layer structure away from the driving backplane, wherein a material of the pad layer structure includes at least one of tin, silver, and copper.

9. The light-emitting substrate according to claim 1, wherein the isolation structure includes:
a third recess, wherein in the direction away from the driving backplane, the third recess penetrates the bonding layer, the first electrode layer, the first semiconductor layer and the light-emitting layer and extends into the second semiconductor layer; and
an insulating layer and a reflective layer that are stacked on sidewalls and bottomwalls of the third recess, wherein the insulating layer is located between the reflective layer and the third recess, and the reflective layer is configured to reflect light directed to the reflective layer.

10. The light-emitting substrate according to claim 9, wherein the third recess includes:
a plurality of first sub-recesses arranged at intervals in a first direction and all extending in a second direction, wherein the first direction intersects with the second direction; and
a plurality of second sub-recesses arranged at intervals in the second direction and all extending in the first direction;
wherein the plurality of first sub-recesses and the plurality of second sub-recesses intersect with each other to constitute a grid structure, and each square in the grid structure defines a light-emitting device.

11. The light-emitting substrate according to claim 9, wherein in a direction perpendicular to a sidewall of the third recess, two portions of the reflective layer respectively covering two opposite sidewalls of the third recess have a first gap therebetween.

12. The light-emitting substrate according to claim 11, wherein
in the direction perpendicular to the sidewall of the third recess, a dimension of the third recess is in a range of 2 μm to 3 μm, inclusive; and/or
a thickness of the insulating layer is in a range of 0.5 μm to 1 μm, inclusive; and/or
a thickness of the reflective layer is in a range of 50 nm to 150 nm, inclusive.

13. The light-emitting substrate according to claim 1, wherein an orthographic projection of the second electrode on the driving backplane is located in an orthographic projection of the isolation structure on the driving backplane.

14. The light-emitting substrate according to claim 13, wherein
in a direction perpendicular to the driving backplane, the second electrode and the isolation structure have a second gap therebetween.

15. The light-emitting substrate according to claim 1, wherein the second electrode includes:
a plurality of first sub-portions arranged at intervals in a first direction and all extending in a second direction, wherein the first direction intersects with the second direction; and
a plurality of second sub-portions arranged at intervals in the second direction and all extending in the first direction;
wherein the plurality of first sub-portions and the plurality of second sub-portions intersect with each other to constitute a grid structure, and each square in the grid structure defines a coloring region.

16. The light-emitting substrate according to claim 1, wherein
in a direction perpendicular to the driving backplane, a dimension of the color conversion layer is in a range of 3 μm to 5 μm, inclusive; and/or
in a row direction in which the plurality of light-emitting devices are arranged, a dimension of the light-emitting device is in a range of 3 μm to 5 μm, inclusive; and in a column direction in which the plurality of light-emitting devices are arranged, a dimension of the light-emitting device is in a range of 3 μm to 5 μm, inclusive.

17. A display apparatus, comprising:
the light-emitting substrate according to claim 1; and
a circuit board connected to the light-emitting substrate and configured to transmit a control signal to the light-emitting substrate.

18. A manufacturing method of a light-emitting substrate, comprising:
forming a device stack layer on a base, wherein the device stack layer includes a second semiconductor layer, a light-emitting layer, a first semiconductor layer, a first electrode layer, and a bonding layer that are sequentially arranged in a direction away from the base;
forming an isolation structure in the device stack layer, wherein the isolation structure penetrates the bonding layer, the first electrode layer, the first semiconductor layer and the light-emitting layer, and extends into the second semiconductor layer, and separates the device stack layer into a plurality of light-emitting devices;
providing a driving backplane and bonding the device stack layer to the driving backplane, wherein the driving backplane includes a plurality of driving circuits, the bonding layer of the device stack layer is bonded to the driving backplane, and a light-emitting device of the plurality of light-emitting devices is connected to a driving circuit of the plurality of driving circuits;
removing the base to expose the second semiconductor layer, wherein the second semiconductor layer includes a plurality of coloring regions arranged in an array, and any adjacent coloring regions having an isolation region therebetween;
forming a plurality of second recesses in a surface of the second semiconductor layer away from the driving backplane, wherein a part of the plurality of second recesses is located in the plurality of coloring regions, and another part of the plurality of second recesses is located in all isolation regions;
forming a first recess in the surface of the second semiconductor layer away from the driving backplane, wherein the first recess is located in the all isolation regions;
forming a color conversion layer in the plurality of second recesses; and
forming a second electrode in the first recess.

19. The manufacturing method according to claim 18, wherein forming the isolation structure in the device stack layer includes:
forming a third recess in the device stack layer, wherein the third recesses penetrates the bonding layer, the first electrode layer, the first semiconductor layer and the light-emitting layer, and extends into the second semiconductor layer, and the third recess separates the device stack layer into the plurality of light-emitting devices; and
sequentially forming an insulating layer and a reflective layer in the third recess, wherein the insulating layer covers sidewalls and bottomwalls of the third recess, and the reflective layer covers a surface of the insulating layer away from the sidewalls and bottomwalls of the third recess and exposes a surface of the device stack layer away from the base.

20. The manufacturing method according to claim 18, wherein forming the plurality of second recesses in the surface of the second semiconductor layer away from the driving backplane includes:
etching the second semiconductor layer by electrochemical etching to form the plurality of second recesses in the surface of the second semiconductor layer away from the driving backplane;
wherein in the plurality of second recesses, at least two second recesses have different opening sizes, and/or at least two second recesses have different opening shapes, and/or at least two second recesses have different depths in a direction perpendicular to the second semiconductor layer; or
forming the plurality of second recesses in the surface of the second semiconductor layer away from the driving backplane includes:
forming an initial mask layer on the second semiconductor layer, wherein the initial mask layer covers the surface of the second semiconductor layer away from the driving backplane;
forming an imprint pattern layer on the initial mask layer, wherein the imprint pattern layer includes a plurality of imprint patterns, and an imprint pattern exposes a portion of the initial mask layer;
etching the initial mask layer by using the imprint pattern layer as a mask to form a first mask layer; and
etching the second semiconductor layer by using the first mask layer as a mask to form the plurality of second recesses in the second semiconductor layer.

21.-27. (canceled)
